(19) United States
(12) Patent Application Publication
(10) Pub. No.: US 2025/0270240 A1
(43) Pub. Date: Aug. 28, 2025

(54) ORGANOMETALLIC COMPOSITIONS WITH POLYENE LIGANDS, RADIATION SENSITIVE COATINGS WITH BRIDGING ORGANIC LIGANDS AND PATTERNING

(71) Applicant: Inpria Corporation, Corvallis, OR (US)

(72) Inventors: Robert E. Jilek, Philomath, OR (US); Christopher J. Reed, Corvallis, OR (US); Matthew Voss, Corvallis, OR (US)

(21) Appl. No.: 19/059,783

(22) Filed: Feb. 21, 2025

Related U.S. Application Data
(60) Provisional application No. 63/557,166, filed on Feb. 23, 2024.

(51) Int. Cl. C07F 7/22; G03F 7/004

(52) U.S. Cl. CPC C07F 7/2224; G03F 7/0042

(57) ABSTRACT

Organometallic precursor compositions containing a polyene ligand, such as a diene ligand, are described. Corresponding films are also described and show promising solubility behavior. A synthesis technique is described for forming a polyene-containing organotin trialkoxide compound. The incorporation of polymerization inhibitors and/or blends of organotin compounds with different ligands are described as a way to design radiation sensitive films to have target solubility properties.

### CROSS REFERENCE TO RELATED APPLICATIONS

This application claims priority to copending provisional application 63/557,166 filed Feb. 23, 2024 to Jilek et al., entitled “Organometallic Compositions with Diene Ligands and Patterning,” incorporated herein by reference.

### FIELD OF THE INVENTION

The invention relates to organometallic, in particular organotin, patterning compositions having diene containing ligands. Specifically, the diene ligands can participate in chemistry that leads to additional routes of contrast generation, while also enhancing the absorbance and/or quantum efficiency of EUV exposure. By enabling photochemistry to occur on or within the ligands, the dose sensitivity of the organotin resist can be improved relative to non-diene ligands.

### BACKGROUND OF THE INVENTION

Organometallic compounds provide metal ions in solution and vapor forms for deposition of thin films. Organotin compounds provide high EUV absorption and radiation sensitive tin-ligand bonds that can be used to lithographically pattern thin films. The manufacture of semiconductor devices at ever shrinking dimensions with EUV radiation requires new materials with wide process latitude to achieve required patterning resolutions and low defect densities.

### SUMMARY OF THE INVENTION

In a first aspect, the invention pertains to an organometallic compound represented by the formula RSnL₃, wherein R is an organo group with 1 to 31 carbon atoms and at least two conjugated C═C bonds and forms a C—Sn bond, and each L is independently a hydrolysable ligand. A solution can comprise an organic solvent and this organometallic compound with a ligand having conjugated C═C bonds. The solution can be used in a method for forming a radiation patternable coating comprising a step of depositing the solution onto a substrate to form a radiation sensitive organometallic film. In some embodiments, the solution can further comprise a polymerization inhibitor compound. In additional or alternative embodiments, the solution can further comprise a second organometallic composition represented by the formula R^{a}SnL₃ and distinct from the organometallic compound, wherein L is a hydrolysable ligand and R^{a} is an organo group with 1 to 31 carbon atoms and forming a C—Sn bond. A structure can comprise a radiation sensitive organometallic film and a substrate supporting the radiation patternable film on a surface, wherein the film comprises the organometallic compound with the ligand having the conjugated C═C bonds and/or a reaction product of the organometallic compound. A method for forming a radiation patternable coating can comprise the step of depositing the organometallic compound with the ligand having the conjugated C═C bonds onto a substrate.

In a further aspect, the invention pertains to a method for synthesizing a (polyene-containing) monoorgano tin trialkoxide, the method comprising the step of reacting MSn(OR′)₃ with RY to form RSn(OR′)₃, in which M is an alkali metal, Y is an organosulfonate group, R is an organo group with 1 to 31 carbon atoms and forming a C—Sn bond in the product RSn(OR′)₃; and R′ is an organo group with 1 to 10 carbon atoms.

In another aspect, the inventio pertains to a radiation sensitive film comprising a network with Sn (IV) atoms, oxo ligands and hydroxo ligands, and with polymerized/crosslinked polyene ligands with a plurality of C—Sn bonds. A structure can comprise the radiation sensitive film on a substrate surface.

In an additional aspect, the invention pertains to a method of patterning a radiation sensitive film, the method comprising:
forming a radiation sensitive organometallic film on a substrate surface comprising depositing onto the surface a solution comprising an organic solvent, an optional polymerization inhibitor and one or more organometallic compounds represented by the formula RSnL₃, where R is an organo group with 1 to 31 carbon atoms and with at least one organometallic compound having at least two conjugated C═C bonds, and forms a C—Sn bond, L is a hydrolysable group; and
irradiating the radiation sensitive organometallic film, following hydrolysis of hydrolysable ligands to form an oxo-hydroxo network, with patterned radiation to form a virtual image having irradiated regions and non-irradiated regions. In some embodiments, the radiation sensitive film comprises a polymerization inhibitor. In additional or alternative embodiments, the solution comprises a second organometallic compounds represented by the formula R^{a}SnL′₃, wherein R^{a} is an organo group with 1 to 31 carbon atoms and forming a C—Sn bond and free of conjugated polyene functionality and L′ is a hydrolysable group that is the same or different form L.

### BRIEF DESCRIPTION OF THE DRAWINGS

FIG. 1 is a ¹H NMR spectrum of 3-methylene-pent-4-en-yltin tris(tert-butyl oxide) (EBDSn(OtBu)₃).

FIG. 2 is a ¹¹⁹Sn NMR spectrum of 3-methylene-pent-4-en-yltin tris(tert-butyl oxide) (EBDSn(OtBu)₃).

FIG. 3 shows chemical formulas for various precursors available via the disclosed methods.

FIG. 4 is a plot of FTIR spectra as a function of bake temperature for a set of films prepared from a coating solution comprising 3-methylene-pent-4-en-yltin tris(tert-butyl oxide) (EBDSn(OtBu)₃).

FIG. 5 is a plot of the thickness normalized peak area versus temperature for the FTIR spectra of FIG. 4.

FIG. 6 is a plot of GC-MS as a function of bake temperature for a set of films prepared from a coating solution comprising 3-methylene-pent-4-en-yltin tris(tert-butyl oxide) (EBDSn(OtBu)₃).

FIG. 7 is a continuation of the plot of FIG. 6 at longer times.

FIG. 8 is a plot of GC-MS as a function of bake temperature for a set of films prepared from a coating solution comprising t-butyltin tris(tert-butyl oxide) (t-BuSn(OtBu)₃).

FIG. 9 is a plot of FTIR spectra as a function of bake temperature for a set of films prepared from a coating solution comprising 2-methyl-4-pentenylSn(OtBu)₃.

FIG. 10 is a plot of FTIR spectra as a function of bake temperature for a set of films prepared from a coating solution comprising n-butyltin tris(tert-butyl oxide) (n-BuSn(OtBu)₃).

FIG. 11A is a plot of the thickness normalized peak area versus temperature for the FTIR spectra of FIG. 6.

FIG. 11B is a plot of the thickness normalized peak area versus temperature for the FTIR spectra of FIG. 10 with an extrapolation to the decomposition temperature.

FIG. 12 shows chemical formulas for precursors B-D referenced in the examples.

FIG. 13 shows a set of SEM micrographs for six patterned organotin coatings formed with a diene-containing precursor (S2 and S3) or without a diene-containing precursor (S1) and irradiated with the indicated EUV dose and baked at the indicated PEB temperature.

FIG. 14 shows UV-Visible spectra for a photoresist film prepared from a diene-containing precursor composition at three periods during processing: after a PAB, after a subsequent 30 mJ/cm² EUV exposure, and after a subsequent PEB.

FIG. 15 shows UV-Visible spectra for a set of photoresist films prepared from a diene-containing precursor composition after exposure to a selected EUV radiation dose: 0 mJ/cm², 30 mJ/cm², or 100 mJ/cm².

FIG. 16 shows UV-Visible spectra for a set of EUV irradiated and subsequently baked photoresist films prepared from diene-containing precursor solutions having no polymerization inhibitor (S6), a 4-hydroxy TEMPO polymerization inhibitor (S7), or a BHT polymerization inhibitor (S8).

FIG. 17 is a set of plots for samples with no polymerization inhibitor, with 4-hydroxy-TEMPO or with BHT, taken after a post application bake, after a further 45 minute rest period and after a post exposure bake performed after the rest period.

FIG. 18 is a cartoon depicting the disruption of clustering induced by bridging of ligands from diene crosslinking.

### DETAILED DESCRIPTION OF THE INVENTION

Organotin compositions having organic ligands with conjugated olefinic functionality, such as dienes, can offer advantages for some patterning applications. For example, diene ligands, with optional heteroatom substitution, can allow for chemistry to occur within the organic ligand to afford additional routes of contrast generation. Additionally, diene ligands, with optional heteroatom substitution, can enhance the absorbance and/or quantum efficiency of EUV exposure. By enabling photochemistry to occur on or within the diene ligands ligand, the dose sensitivity of the organotin resist can be improved relative to ligands without diene functionality. The ability of photochemistry to occur on the organic ligand can provide for a method to enhance contrast between unexposed and exposed regions of the material in addition to or alternatively to cleavage of the Sn—C bond. In particular, films prepared from organotin compositions having organic ligands with diene functionality have been observed to be insoluble in organic solvents following coating, which is in direct contrast to organotin compounds having organic ligands without diene functionality and which implies some chemistry is taking place in the compositions during the coating process. The degree of crosslinking of the diene functional groups can be controlled by blending with precursors with other, non-polymerizable organic ligands and/or through the use of polymerization inhibitor compounds, such as radical scavengers, in the precursor solutions at appropriate concentrations. Through the control of the degree of crosslinking, precursors with diene ligands can be used to form patternable coating suitable for either positive tone or negative tone pattern formation. Additional reactions are observed to take place during a post-application bake (PAB). Due to additional routes to contrast enhancement, the need for low-stability tertiary C—Sn bonds can be alleviated and more thermally stable C—Sn bonds, such as with organic ligands having primary or secondary alpha carbons bound to the Sn, can be used, although blends can be used with various ligands. The transformation of the initial radiation patternable coating into an effectively insoluble film, may be leveraged to improve positive tone patterning. The resulting radiation patternable films are also found to undergo less shrinkage during process, which can facilitate predictable patterning and predicting critical dimensions. Organotin compositions with blends of organic ligands can allow for adjustment of patternable coatings with adjustable properties.

The loss of solubility of the coatings formed with the diene comprising ligands along with other measurements strongly suggest that a chemical reaction is taking place. While not wanting to be limited by theory and consistent with some of the observations, it is believed that the reactions involve polymerization of the diene ligands that effectively crosslink the coating. The observations of film insolubility after deposition suggest that some reactions can occur before a post application bake step. Further reactions can take place during and/or following a post coating and pre-irradiation bake step. As expected, above certain bake temperatures, organic components are released from the coating. In some embodiments, the diene-containing organotin composition can be used as an underlayer film. Owing to the propensity towards reactions in the film and corresponding insolubility of the films prepared from diene organotin precursor compositions, such films can be useful as coatings and/or underlayers.

The underlayer films prepared from the diene-containing organotin compositions can be useful as underlayers for both other organotin photoresist compositions and for non-organotin photoresist compositions. The insolubility of the underlayers formed from diene-containing precursors, in a variety of solvents, allows for the underlayer to be compatible with a variety of photoresist compositions. The diene-derived underlayer films are stable at reasonable processing temperatures and they have surface properties, such as relatively low contact angles and moderate polarities, that can be useful as surfaces for subsequent deposition of films based on other organotin photoresist compositions, allowing for improved adhesion. The high tin content of the underlayers can enable improved etch resistance over conventional organic polymer-based materials and can allow for improved etch selectivity with respect to other materials in the patterning stack. The underlayer films prepared from the diene-containing organotin compositions can be used as hardmask layers in patterning stacks, allowing transfer of patterns into desired layers by appropriate selection of etch chemistries, such as halide plasmas (e.g., BCl₃, HBr), oxygen-based plasmas, wet etches, and so forth.

For the photoresist compositions comprising organotin precursors having polyene (e.g., diene) ligands, Applicant has found desirable results from using blends of precursors with different organo ligands to introduce properties of each. As described in detail below, blends of the polyene ligands with other ligands provides an approach to control the degree of reaction between polyene ligands due to effective dilution and corresponding spacing afforded by the presence of the non-diene ligands. It can therefore be desirable to blend the polyene ligands described herein with other organo ligands to modify the properties of the blended photoresist films, such as solubility and radiation sensitivity, and some examples are presented below.

In some embodiments, the organic ligands can comprise olefinic ligands having two or more unsaturated carbon bonds. The presence of polyolefinic functionality within the organic ligand can allow for thermally and/or radiolytically induced cross linking or polymerization within the film without substantial Sn—C cleavage. Some results suggest that these reactions can take place prior to performing any heating, although further reactions may take place upon subsequent heating. Polymerization of the organic ligands can lead to significant changes in molecular weight of species within the irradiated areas of the film and can thus significantly alter the solubility of such regions in an appropriate developer. Applicant has previously reported the synthesis of organotin compositions with organic ligands having a single unsaturated bond, specifically a 2-butene based ligand. See published U.S. patent application 2024/0199658 to Jilek et al. (hereinafter the '658 application), entitled “Direct Synthesis of Organotin Alkoxides,” U.S. Pat. No. 10,787,466 to Edson et al. (hereinafter the '466 application) entitled “Monoalkyl tin compounds with low polyalkyl contamination, their compositions and methods”, and published U.S. patent application 2022/00064192 to Edson et al. (hereinafter the '192 application), entitled “Methods to Produce Organotin Compositions With Convenient Ligand Providing Reactants,”, all of which are incorporated herein by reference. The monoalkenyl ligands show different behavior from the present diene ligands.

An unexpected and surprising result of organotin films formed from the deposition of organotin precursors comprising diene ligands is the general insolubility of the as-deposited films which is believed to be a result of the polymerization of the diene ligands during and/or immediately after deposition. Further polymerization and/or crosslinking may occur during subsequent heating steps prior to irradiation. Unless specifically indicated otherwise, polymerization and crosslinking terms are used interchangeably to reflect chain growing processes that are linear or branched or mixed. Applicant has discovered that this polymerization behavior is markedly different than other monoalkyltin compounds having only a single C═C bond that have been synthesized and deposited. In contrast to these previously described organotin precursor compounds with alkene ligands, the organotin precursor compounds comprising diene ligands described herein appear to undergo rapid polymerization during deposition and/or with mild heating to form insoluble films. As described in the examples, blending of the precursors with diene containing ligands with precursors with other ligands can result in films with suitable solubility while retaining some of the effects of the diene ligands.

In some cases, it can be desirable to control the polymerization of the diene organotin composition such that polymerization occurs to a desired degree, which may be evaluated using solubility, and at a desired time during the processing of the film, such as during deposition, subsequent heating, and/or the radiation-exposure process. Along with control of process conditions, control of diene polymerization can be achieved through precursor blending and/or inclusion of a polymerization inhibitor, such as a radical scavenger. In some embodiments, the polymerization of the diene ligands can occur during a PAB process wherein the film is heated after deposition but prior to exposure to radiation. In some embodiments, the polymerization of the diene ligands can occur during exposure to radiation. In some embodiments, the polymerization of the diene ligands can occur during a post-exposure bake.

While not wanting to be limited by theory, the polymerization of the diene ligands is believed to occur through a free radical polymerization process although other polymerization processes can occur, such as ion based polymerization. Upon initiation of radical polymerization, a radical initiator interacts with the diene ligand to form a radical organotin species that can further propagate the reaction to ultimately result in a crosslinked organotin material with a polymerized C—C bond network. The C—C bond network can feature cis- and trans-conformations of the various monomeric species, branched structures, and unsaturated bonds with polymerized structures that are based on the identity of the different monomeric diene reactants. Similarly, if the diene ligand is present in a blended composition that comprises additional organotin compounds, the polymerized network to some extent may or may not incorporate such organo ligands as part of the overall polymerized structure. In any case, the polymerization of the diene ligands generally results in a crosslinked material which has species of larger molecular weights, resulting in insolubility of the material. Approaches described herein to limit the degree of polymerization can be used to control the growth of molecular weight of the species in the crosslinked material. Prior to irradiation and cleavage of the carbon-tin bonds, the polymerization of the polyenes can provide a separate networking of the tin in conjunction with the oxo-hydroxo network. Irradiation can be used to cleave the carbon-tin bonds, and the polymerization of the polyenes can result in separated polymers/oligomers along with condensation of the tin oxo-hydroxo networks.

Organotin compounds used for precursors are prone to hydrolysis. Excess water can lead to instability and gelation. A more modest amount of water for hydrolysis tends to support cluster formation. In precursor solutions with relatively low water content, it is generally believed, with some observational support, that transient clusters of various stoichiometries can form. With a somewhat greater water content, dodecamers are believed to be thermodynamically favored. With appropriate synthesis approaches, stable organotin oxide hydroxide clusters can be formed, and these have been used for patterning. See, for example, U.S. Pat. No. 11,392,028 to Cardineau et al., entitled “Tin Dodecamers and Radiation Patternable Coatings With Strong EUV Absorption,” and Cardineau et al., “Photolithographic properties of tin-oxo clusters using extreme ultraviolet light (13.5 nm),” Microelectronic Engineering, 127 (2014) 44-50, both of which incorporated herein by reference. During the deposition process to form a patternable organotin oxide hydroxide film, hydrolysis and condensation of monoorganotin precursors is generally sufficiently rapid that an amorphous film comprising an organotin oxo-hydroxo network is formed on the substrate, alleviating the impetus to specifically form clusters prior to deposition. The rapid hydrolysis/condensation processes that occur during deposition of monoalkyltin precursors having hydrolysable ligands can be beneficial in avoiding inhomogeneities in the coating due to the presence of larger clusters, and which can therefore inhibit desirable patterning performance. Consistent with the formation of an organotin oxide hydroxide network, the films formed with the diene ligands exhibit UV-visible absorption spectra that suggest some formation of cluster-like species in the films. For example, amorphous organotin oxide hydroxides solids, such as organotin stannoic acids (RSnOOH), are known to share structural similarities with the well-defined species based on the dodecameric motif, [(RSn)₁₂O₁₄(OH)₆]²⁺, such as the presence of 5 and 6 coordinated Sn atoms based on Sn—O—Sn and Sn—OH bonding. Despite these similarities, the amorphous organotin oxide hydroxides and discrete dodecameric clusters can be considered polymorphic materials which share similar compositions but have different properties. As described by Applicant in U.S. Pat. No. 10,228,618 to Meyers et al. (hereinafter the '618 patent), entitled “Organotin Oxide Hydroxide Patterning Compositions, Precursors, and Patterning,”, incorporated herein by reference, the amorphous organotin oxide hydroxide films prepared from hydrolyzing RSnL₃ precursors can be advantageous over films prepared from precursor solutions comprising high concentrations of discrete cluster species, such as organotin dodecamers. For the formation of high-quality, dense, pinhole free organotin film suitable for high-resolution patterning, it is generally desirable to reduce the presence of such cluster-like species in the films. The formation of cluster-like species can be reduced by the polymerization of the diene ligands which, while not wanting to be limited by theory, suggests that polynuclear clusters based on condensed Sn—O—Sn bonds are hindered from forming due to the decreased mobility of Sn atoms in a polymerized organic network. In other words, the tin atoms are believed to be less mobile and less able to condense because of their rigid attachment to the polymerized organic scaffolding. If cluster-like species are present in the film after deposition, subsequent polymerization of the organic groups and the forces resulting therein can introduce strain into the local Sn—O—Sn and Sn—OH bonds, which can disrupt and rip apart these local cluster-like domains in the film. This disruption of the cluster structure induced by bridging of ligands due to crosslinking of polyenes is depicted in a cartoon in FIG. 18. Similarly, exposure to suitable radiation can drive Sn—C bond cleavage which destabilizes the local cluster-like structures in the films and allows for oxide hydroxide network formation. See Haitjema, et al., “Photoreactions of Tin Oxo Cages, Model EUV Photoresists,” Journal of Photopolymer Science and Technology, 30 (1), 2017, 99-102, incorporated herein by reference.

The presence of diene ligands bound to the Sn atoms can frustrate the formation of dodecameric oxo species within the film during heating and other processing steps. While not wanting to be limited by theory, it is believed that the loosely organized and condensed film that forms upon deposition of the conventional organotin precursor compositions can transform into more ordered dodecameric species during thermal processing, such as during a PEB. It is well known that dodecameric clusters are thermodynamically favorable products of hydrolysis of monoalkyltin compounds, and such species can form within the film during heating which can lead to the formation of voids, film inhomogeneity, and/or patterning defects. By including organotin precursors having diene-containing ligands, the ordering and formation of the film material into tin-oxo clusters can be reduced which can be desirable to improve film homogeneity.

The use of blended compositions of organotin precursors comprising a mixture of two or more R—Sn moieties can hinder the formation of well-defined dodecameric species. As shown in the examples below, the ethyl butyl diene ligand can effectively prevent or hinder the formation of dodecameric species in the film. During modest heating, the diene ligands can crosslink to form a network of C—C bonds that bridge between Sn centers which frustrates the ability for the Sn centers to rearrange into the dodecameric structures. In this way, film homogeneity can be improved.

It has also been discovered that the presence of diene ligands in the film can increase the hydrophilicity of the surface of the film. While not wanting to be limited by theory, it is believed that the diene ligands crosslink and disrupt the formation of micellular dodecameric organotin oxo-hydroxo species. The Sn oxo-hydroxo centers are hindered from condensing to form dodecameric species which are generally reverse-micelles wherein the hydrophilic Sn—O bonds are facing inward and the hydrophobic R—Sn bonds are facing outwards. Therefore, by hindering the formation of dodecameric species in the film hydrophilic Sn—O and Sn—OH bonds can be more evenly distributed throughout the film which can improve the hydrophilicity of the film. Film hydrophilicity can generally be measured by water droplet contact angle. Improved hydrophilicity can be desirable for aqueous development processes, such as positive-tone development with aqueous base, such that better wetting, coverage, and interaction between the film and the developer solution is achieved.

The potential structures for R ligands is generally detailed below. With respect to the diene R ligands, these can be RₚₑR⁰C(R¹R²)—, where C is a carbon atom bonded to the Sn atom, R¹ and R² are independently hydrogen or saturated alkyl groups with 1-5 carbon atoms and optional heteroatoms, R⁰ is a bond or an saturated alkyl group with 1 to 5 carbon atoms with optional heteroatoms, and Rₚₑ is a polyene moiety, such as a diene moiety. If R¹ and R² are hydrogen, then C bonded to Sn is a primary carbon, if one of R¹ and R² is hydrogen, then C bonded to Sn is a secondary carbon, and if neither R¹ nor R² is hydrogen, then the C bonded to Sn is a tertiary carbon. In some embodiments, R¹ and R² are hydrogen and R⁰ is CR³R⁴, where in some embodiments R³ and R⁴ are independently H, F, I, or CH₃. In general, primary carbons are bonded to tin stronger than secondary carbons, and secondary carbons are bonded more strongly to tin than tertiary carbons. To lower the dose to cleave the tin-carbon bond, the order of the carbon can be correspondingly increased to lower the bond strength.

Examples are presented below with 3-methylene-pent-4-en-yl (EDB) ligand having R⁰ equal to —(CH₂)—, R¹ and R² being hydrogen, and Rₚₑ being —C(═CH₂)—C═CH₂. Rₚₑ generally has a polyene structure with non-branched or branched carbon chains with two or more conjugated carbon-carbon double bonds that share a common atom. The conjugated diene ligands described herein provide for the observed insolubility from the polymerization reactions described above. For diene embodiments, Rₚₑ can be represented as (1, 3-diene-C₄R′₅), where each of the 5 R′ are independently H, a halogen, such as F, or an alkyl group with 1-5 carbon atoms and optional heteroatoms (e.g., —CH₃ or —CF₃). While acyclic polyenes are of particular interest for polymerization, cyclic polyenes are known in carbocycle and heterocycle forms. Examples of carbocycles include, for example, 1,3 cyclohexadiene. Heterocycles include, for example, furan, thiophene, and 2H-pyran. The ring compounds are also amenable to synthesis using the synthetic processes described herein.

With respect to positive tone patterning, the radiation-induced cleavage of the Sn—C bonds results in the formation of polar species comprising Sn—OH and Sn—O bonds, and these polar species can be further promoted during post-exposure heating processes as the exposed material reacts with ambient air and humidity. The formation of polar species can further increase the solubility of the exposed material in a suitable polar developer, such as an aqueous base.

Inclusion of the heteroatoms such as O and S in the diene ligand can improve the hydrophilicity of the polymerized films while not necessarily increasing their solubility which is beneficial for positive-tone development with an aqueous developer. The increase in hydrophilicity associated with the inclusion of O and S heteroatoms, such as in the furan and thiophene structures above, can improve the wettability and surface interaction of the developer liquid with the photoresist material. The improved wettability allows for better cross-wafer uniformity of the development process.

Synthetic routes to conjugated olefinic organotin compositions, such as diene-containing organotin trialkoxides, have been discovered based on modified synthetic routes described in the '658. The methods offer high selectivity and efficiency and are based on reaction of an alkali metal tin(II) trialkoxide, such as potassium tin(II) trialkoxide (KSn(OR′)₃) with an organo (alkyl) halide, organo (alkyl) mesylate, or organo (alkyl) tosylate (p-CH₃C₆H₄SO₃⁻) or a similar alkyl sulfonate compound (RSO₃⁻, where R is the organo ligand to be bound to the Sn and can have the scope discussed herein for the R ligand), to form a monoorganotin trialkoxide composition. The alkali metal tin(II) trialkoxide is represented by the formula MSn(OR′)₃, wherein M is Li, Na, K, Rb, or Cs, although the structure in solution has not been directly determined. (KSn(OR′)₃) is a desirable bimetallic alkali metal tin trialkoxide since it is an effective and shelf-stable reagent. For the synthesis of the ethylbutadiene (EBD) tin trialkoxide described in the Examples herein, it was observed that the purity of the product was improved through the use of the alkyl tosylate (EBD tosylate) reactant compared to the use of the alkyl bromide (EBD bromide) reactant. Related synthesis routes are described in the '658 application cited above using the halides. The methods described herein can provide for high selectivity and yield using the tosylates or other alkyl sulfonates and enable the preparation of monoorganotin trialkoxide compositions without the need to perform ligand exchange or conversion reactions, for example, conversion of a monoalkyltin triamide to a monoalkyltin trialkoxide. While the focus herein is directed to polyene ligands, the synthesis using the alkyl sulfonates can be used generally with any organo ligand with effective results, and a range of R ligands are summarized below. The reactions described herein can be useful for preparing monoorganotin trialkoxides having primary Sn—C bonds. In some embodiments, the primary carbon Sn—C bonds connect an organic ligand having conjugated carbon-carbon double bonds to a tin atom. Furthermore, the reactions described herein can be useful in preparing organotin compounds with polyene R groups substituted with heteroatom functional groups. Ligands with heteroatoms are described in the '658 application using similar synthesis approaches. The resulting conjugated olefinic organotin trialkoxides, especially dienes, can be desirable precursors for radiation based patterning compositions, especially for effective EUV patterning and positive tone patterning. Dienes of interest include, for example, 2-ethyl-1,3-butadiene, which is exemplified, and isoprene, 2-methy-1,3-butadiene, as well as derivatives thereof with heteroatom substitutions.

The resulting conjugated olefinic organotin trialkoxides can also be desirable precursors for the formation of underlayers. The insolubility of the films formed from coating the olefinic organotin precursors suggests a compatible underlayer to provide patterning processing flexibility. The conjugated olefinic organotin underlayer films prepared from these precursors provide for a high degree of thermal stability which can be advantageous for high-temperature processing of the photoresist, such as during a post-exposure bake (PEB) or hard bake, during the lithographic patterning process. Underlayers prepared from the conjugated olefinic organotin compounds can enhance adhesion between the resist, for example, an organotin resist, and the underlayer film. Similarly, the underlayers prepared from the conjugated olefinic organotin compounds can be useful in lithographic processes using conventional polymer-based photoresists, such as chemically amplified resists (CARs), due to the high etch contrast between the tin-rich underlayer and the carbon-rich resist layer, in which the underlayer can act as a hardmask to provide control over pattern transfer.

As used herein, and as generally consistent with usage in this field, “organotin,” “hydrocarbyl tin” and “alkyl tin” terms can be used interchangeably, and likewise “monoalkyl” can be used interchangeably with “monoorgano” or “monohydrocarbyl”. The “alkyl” ligands suggest bonding to the tin with carbon (generally sp³ or sp² hybridized) to form a bond that is generally not hydrolysable through contact with water. The “alkyl” group can also have internal unsaturated bonds and hetero-atoms, i.e., distinct from carbon and hydrogen, that are not involved in bonding with the tin. “Olefin” or “olefinic” refers to an alkyl group that contains one or more C═C bonds, with “conjugated” referring to an olefin that has two C═C bonds separated by a single C—C bond. The term “alkene” can be used interchangeably with “olefin.” Similarly, a reference to alkoxide groups refers to group bound at an oxygen atom with an organo substituent on the oxygen. New synthesis methods described herein yield monoalkyl tin trialkoxides in high yield and with low (non-tin) metal and polyalkyl (i.e., polyhydrocarbyl) contaminants following straightforward purification. The synthesis approaches are amenable for efficient scale up for commercial production, and the reactions are straightforward and can be performed as a single pot synthesis.

Organotin compounds, particularly monoalkyltin trialkoxide and triamide compounds, have found use as precursors for high-performance photoresists for EUV lithography. The use of alkyl tin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and the above-referenced '618 patent both of which are incorporated herein by reference.

The compositions synthesized herein can be effective precursors for forming the organo tin oxo-hydroxo compositions that are advantageous for high resolution patterning, for example in extreme ultraviolet (EUV), ultraviolet (UV), electron-beam lithography. The organo tin precursor compositions comprise a group that can be hydrolyzed with water or other suitable reagent under appropriate conditions to form the monoorgano tin oxo-hydroxo patterning compositions, which, when fully hydrolyzed, can be represented by the formula RSnO_{(1.5-(x/2))}(OH)ₓ where 0<x≤3. It can be convenient to perform the hydrolysis to form the oxo-hydroxo compositions in situ, such as during deposition and/or following initial coating formation. While organo tin triamides and organo tin triacetylides described, for example, in the above-referenced '618 patent, can be used under hydrolyzing conditions for forming radiation sensitive coatings for patterning, it can be desirable to use organo tin trialkoxides as part of the film-forming compositions. Direct synthesis of organo tin trialkoxides are described herein.

Monoorgano tin compositions can generally be represented by the formula RSnL₃, where R is an alkyl group and L is a hydrolysable ligand. For processing to form radiation patternable coatings, L is generally hydrolysed before or during (e.g., in-situ) deposition, and/or after deposition (e.g., in a post application bake) to result in a coating comprising a polymeric organotin oxo-hydroxo composition on a substrate wherein the Sn—R bonds remain substantially intact. As a result, a radiation patternable coating having radiation-sensitive Sn—R (Sn—C) bonds can be realized.

The new synthesis described herein is advantageous for efficient formation of R—Sn bonds with a wide selection of R groups having olefinic functionality and/or heteroatom(s) that can offer improvements in thermal stability and/or photosensitivity over R groups having non-olefinic and/or non-substituted alkyl groups. The synthesis herein using the organo tosylate (or other organo sulfonate) reactant are analogous to the organo halide based reactions in the '685 application cited above, and the '658 application exemplified more suitable ligands. The tosylate reactants are desirable relative to corresponding halide reactants since they can result in a purer product while exhibiting similar ligand versatility, although the halide reactants have been found to be very effective for a range of R ligand products. In some embodiments, it is generally believed that the presence of R ligands in the film forming material hinders extended network formation and condensing of the organotin film, and irradiation of the material can result in the cleavage of Sn—C bonds which, in turn, allows for subsequent processing to condense and/or densify the film. Thus, the radiation sensitive ligand provides a radiation cleavable bond to drive contrast formation upon irradiation between irradiated and non-irradiated sections of the film. In embodiments in which the R groups have conjugated olefinic functionality, while not wanting to be limited by theory, the R ligands may promote extended network formation, such as via intermolecular organic ligand polymerization and/or crosslinking, which is suggested by the change in solubility. In some embodiments, it is believed that intermolecular organic ligand polymerization/crosslinking occurs upon deposition and/or with mild heating. Example 6 describes the solubility of films prepared from a diene-containing precursor (EBDSn(OtBu)₃) as a function of baking conditions. After depositing the precursor and without baking the deposited film, it was observed that the diene-containing precursor formed films were generally highly insoluble by virtue of being only slightly affected or not visibly affected by solvents having a variety of polarities. Example 6 contrasts this solubility with films prepared with precursors lacking conjugated double bonds. Fourier transform infrared (FTIR) measurements suggest potentially more complex reactions during the extended network formation and condensation.

At the time of radiation patterning, hydrolysable ligands have generally been substantially removed to form the ultimate patterning composition from the precursor compositions. In general, organometallic radiation sensitive resists have been developed based on organo tin compositions, such as alkyltin oxide hydroxide, approximately represented by the formula R_{z}SnO_{(2-z/2-x/2})(OH)ₓ, where 0<x<3, 0<z≤2, x+z≤4, and R is a hydrocarbyl or organo group forming a carbon bond with the tin atom. Particularly effective forms of these compositions are mono-organotin oxide hydroxide, in which z=1 in the above formula, and the mono-organotin compositions are the focus herein. In general, R can be a moiety with 1-31 carbon atoms with one or more carbon atoms optionally substituted with one or more heteroatom functional groups, such as groups containing O, N, Si, Ge, Sn, Te, and/or halogen atoms, or an alkyl, or a cycloalkyl further functionalized with a phenyl, or cyano group. In embodiments of particular interest, R can be a moiety with 5-31 carbon atoms and two or more C═C bonds optionally substituted with one or more heteroatom functional groups, although the synthesis reactions are applicable to a wide range of ligands beyond polyenes. For precursors with polyene ligands, such as dienes, these can be incorporated into blends with different R ligands, and the broader description of the organo R ligands are available for combining with polyene comprising ligands. This general discussion can be understood in the context of the discussion above on the range of polyene based organo R ligands should be considered in the context of this broader discussion both in terms of the nature of the hydrolyzed films and precursor blends, which are described further below. In some embodiments, the R groups have two or more C═C bonds, generally conjugated, which exhibit significantly different properties from composition with other organo R ligands when formed into films. In some embodiments not involving polyenes, R can comprise ≤10 carbon atoms and can be, for example, methyl, ethyl, propyl, isopropyl, butyl, t-butyl, isobutyl, silyl, or t-amyl. Generally for saturated and unsaturated embodiments, the R group can be a linear, branched, (i.e., secondary or tertiary at the metal-bonded carbon atom), or cyclic hydrocarbyl group. Each R group individually and generally has from 1 to 31 carbon atoms with 3 to 31 carbon atoms for the group with a secondary-bonded carbon atom and 4 to 31 carbon atoms for the group with a tertiary-bonded carbon atom, optionally with unsaturated or aromatic carbon bonds. In particular, branched alkyl ligands can be desirable for some patterning compositions. The formation of the oxo-hydroxo coating material can comprise deposition of a tin composition with hydrolysable bonds, such as RSnL₃, where L is a hydrolysable ligand, such as an alkoxide, a dialkyl amine, an acetylide or other suitable hydrolysable ligand. The hydrolysable ligands can be hydrolyzed to form the oxo-hydroxo network during deposition of the coating and/or in the coating following deposition, i.e., completing the hydrolysis after deposition. Applicant has developed methodologies to efficiently and effectively form a wide range of patterning compositions with different R groups, optionally with various hetero atoms, with C—Sn bonds, as described further in the '192 application, as well as in the synthesis references provided above.

The thermolytic and radiolytic stability of the Sn—C bond can generally depend on the substitution of the alpha carbon (the C atom bound to the Sn atom), and the stability generally increases as the alpha carbon substitution decreases. For example, Sn—R bonds with primary alpha carbons are generally more stable than secondary alpha carbons which are in turn more stable than tertiary alpha carbons. Some unsaturated alpha carbons, such as an alkynyl C bound to Sn (e.g., Sn—C≡C), are also hydrolytically sensitive and may hydrolyze during processing, and thus they may not be suitable for reliance on their radiation sensitivity. Stability of Sn—C bonds can correlate with dose sensitivity and/or thermal stability such that lower stability Sn—C bonds require less energy to cleave, and therefore may be expected to correlate with lower doses needed to form a pattern. Additionally, thermal stability of the Sn—C bonds can depend on alpha carbon substitution in the same way where increasing substitution of the alpha carbon can generally lead to undesirable tradeoffs between lower thermal stability and higher dose sensitivity. It is therefore desirable for new organotin compositions to have both high thermal stability and high dose sensitivity.

Processing of the organotin precursor compositions to afford organotin oxo-hydroxo coatings generally involves hydrolysis of the RSnL₃ composition(s) to afford the related organotin oxo-hydroxo composition(s). Hydrolysis can be performed prior to the deposition process to yield soluble organotin oxo-hydroxo species (i.e., clusters, oligomeric species, etc.) These soluble organotin oxo-hydroxo species can then be dissolved and/or dispersed into a suitable solvent to form an organotin photoresist solution that can then be used to form radiation-patternable organotin oxo-hydroxo coatings. Alternatively, to maintain greater control over the film forming process, the hydrolysable organotin precursor compositions can be directly dissolved in a suitable solvent to form a photoresist solution that can then be used to form radiation-patternable organotin oxo-hydroxo coatings following hydrolysis. The organotin compositions can also be hydrolysed in-situ with water, which can be ambient water vapor, during the substrate coating process, such as during solution deposition or during vapor deposition, and/or following coating prior to irradiation. Various processing options are described further in the '684 and '618 patents referenced above.

For organotin photoresist precursor compositions wherein the organotin compound(s) dissolved into a solvent for spin-coating, organotin trialkoxides (RSnL₃, L=OR′) can be desirable for use over other RSnL₃ compositions (e.g, organotin triamides, L=NR′₂). Some advantages to organotin trialkoxide compositions are, for example, the production of more benign side-products, e.g., alcohols, that are relatively innocuous compared to the production of gaseous products (e.g., amines) which may cause contamination, environmental health and safety (EHS), and similar concerns within the wafer track and/or wafer fab. Organotin trialkoxides are generally soluble in desirable process solvents and also possess appreciable vapor pressures and low melting points which makes them attractive compounds for use in vapor deposition methods to prepare radiation patternable coatings.

Synthesis of organotin trialkoxide compounds have been previously described, such as in previous patent applications by Applicant. However, these reactions offering monoalkyltin trialkoxides as products generally involve conversion of a non-alkoxide alkyl tin compound into an alkyl tin alkoxide rather than a direct synthesis. In other words, organotin trialkoxides have generally been synthesized through ligand replacement reactions. For example, organotin trialkoxides can be prepared from the corresponding organotin trichlorides by reaction with an alkali metal alkoxide, e.g., KOR′, NaOR′, and the like, according to the following reaction:

RSnCl₃+3 MOR′\grave{a}RSn(OR′)₃+3MCl, (1)

Using this synthetic scheme, the potential product space for organotin trialkoxides therefore has practical constraints based on the access to and purity of the corresponding organotin trichloride. Organotin trichlorides are generally synthesized through the well-known Kocheskov Reaction where a tetraalkyl tin, R₄Sn, serves as a starting material for the synthesis of other organotin halides that are generated through redistribution reaction with SnCl₄. This reaction is known to be non-selective and highly sensitive to stoichiometry, and generally results in some distribution of off-target and undesired RₙSnCl₄₋ₙ products. For example, to synthesize RSnCl₃, a mixture of SnCl₄ and R₄Sn are reacted in a 3 to 1 ratio to target RSnCl₃ as the major product, but the reaction produces significant amounts of R₂SnCl₂ and R₃SnCl as side products which can be difficult to reduce to desirable levels via subsequent purification processes. For semiconductor applications where high purity compounds are required for low defect processing and for commercial viability, one or more purification steps can be necessary to further purify and/or isolate the RSnCl₃ compound prior to its conversion to a trialkoxide, and the purification itself can involve significant effort and can significantly reduce the yield of the target product. The synthetic methods described herein alleviate the need for a high-purity organotin trichloride starting material in the synthesis of an organotin trialkoxide.

Other methods of preparing organotin trialkoxides involve conversion of an organotin triamide to an organotin trialkoxide via the following reaction:

RSn(NR₂″)₃+3HOR′\grave{a}RSn(OR′)₃+3HNR″₂. (2)

While this reaction is relatively straightforward, application of the method can be constrained by factors such as it being exothermic and can potentially lead to decomposition of the reactants and/or products, and high cost because of the necessity of first synthesizing the corresponding organotin triamide. While Applicant has previously described synthesis techniques for preparation of a wide variety of organotin triamides, there remains a desire for access to methods to directly synthesize organotin trialkoxides without the need to first obtain an organotin starting material with the desired R ligand identity. A direct synthesis of a target organotin trialkoxide, RSn(OR′)₃, is desirable and is described herein and in the '658 application.

### Direct Synthesis of Organotin Trialkoxides:

The basic synthesis approach is outlined above. Example 2 describes a method involving the reaction of a diene-containing organotosylate with a metal tin alkoxide compound, such as an alkali metal tin alkoxide, e.g., MSn(OR′)₃, to form a Sn—R bond with R being an ethyl butadiene ligand. In the general method, the alkali metal tin trialkoxide is reacted with the diene-containing (or polyene-containing) organotosylate (or similar organo sulfonate) to form the corresponding diene (polyene)-containing organo tin trialkoxide with low tin contaminant production. While the conjugated dienes have been found to be effective for the purposes described herein allowing for polymerization, higher conjugated unsaturated groups, such as trienes (e.g., CH₂═CH—CH═CH—CR_{Sn}═CH₂, where R_{Sn} is a group with a C—Sn bond) or tetraene, etcetera, can be similarly synthesized and used for film formation.

The alkali metal tin alkoxide (MSn(OR′)₃) can be prepared using methods known in literature, for example, in an article by Veith et al. (hereinafter the Veith article), entitled “Alkoxistannate, II Tri(rerr-butoxi)alkalistannates(II): Synthesis and Structures,” Z. Naturforsch. 41b, 1071-1080 (1986), incorporated herein by reference. The Veith article does not suggest specific reactions using MSn(OtBu)₃ as a further reactant to form alkyltin trialkoxides, e.g., RSn(OtBu)₃. The Veith article discloses the synthesis of MSn(OtBu)₃ using Sn₂(O^{t}Bu)₄. As exemplified herein, MSn(OtBu)₃ is synthesized in a two-step reaction from SnCl₂ and M(OtBu). After the first step, precipitated MCl (KCl) is removed, but no further purification is needed. See also the '658 application.

As described herein, monoalkyltin trialkoxides can be synthesized by the following overall reaction:

MSn(OR′)₃+RX\grave{a}RSn(OR′)₃ (3)

where M is generally an alkali metal, such as Li, K, Na, Cs, or Rb. R′ is generally an organo group with ≤10 carbon atoms, and OR′ can generally be selected for desirable properties of the product monoalkyltin trialkoxide, RSn(OR′)₃, such as stability, melting point, solubility, ease of purification, and so forth. In some embodiments, M is K. In some embodiments, OR′ is tert-butoxide (O^{t}Bu). In some embodiments, OR′ is tert-amyloxide (O^{t}Am). The RX compounds are selected to provide the desired organo ligands, R, for the mono-organotin products. Based on previous work in the '658 application, X can generally be a halide chosen from I, Br, or Cl. The wide availability of RX compounds, where X is a halide, as reactants as well as the broad reactivity of the compounds in the corresponding reaction provides an ability to introduce a wide range of organo ligands into the product monoorgano tin products. Using the alternative reactants with X being tosylate or other sulfonate, better specificity can be achieved for certain R groups, including the non-cyclic dienes described herein.

The reaction of Eq. (3) can be generalized for the synthesis of poly-tin products with bridging organo ligands,

nMSn(OR′)₃+RXₙ\grave{a}R(Sn(OR′)₃)ₙ (4)

where n≥1, such as 1, 2, 3, 4, or more than 4 and M is generally an alkali metal as described above. Such bridging ligands are exemplified in the '658 application using halide “X′ species. In general, as long as reasonable polyhalide reactants are available, there are not clear limits on the number of tin atoms that can be bridged in this way. In some embodiments, n can be from 2 to about 12. R, X and R′ are as specified in the previous paragraph. The polymerization/crosslinking of the polyene ligands provides a way to form bridging ligands with alternative ways to control the process and with the ability to form extensive organic crosslinked networks. The degree of bridging can be controlled using polymerization inhibitors and/or by blending with precursors having other ligands, as described herein.

As described herein and in the Examples below, monoalkyltin trialkoxides can also be synthesized by the following overall reaction:

MSn(OR′)₃+RY\grave{a}RSn(OR′)₃ (5)

where M is generally an alkali metal, such as Li, K, Na, Cs, or Rb. R′ is generally an organo group with ≤10 carbon atoms, and OR′ can generally be selected for desirable properties of the product monoalkyltin trialkoxide, RSn(OR′)₃, such as stability, melting point, solubility, ease of purification, and so forth. In some embodiments, M is K. In some embodiments, OR′ is tert-butoxide (OtBu). In some embodiments, OR′ is tert-amyloxide (OtAm). Y is generally a weak base such as a mesylate, a tosylate group or other suitable sulfonate group, as alternatives to the halides described for Eq. 3. The RY compounds are selected to provide the desired organo ligands, R, for the mono-organotin products. A synthetic pathway is described in Example 2 for forming a sulfonate reactant that can be correspondingly generalized. The synthesis of the sulfonate reactant can be prepared by a reaction that generally involves formation of the desired ligand structure as an alcohol (e.g., 3-methylenepent-4-en-1-ol in Example 2 below) which can then be reacted with sulfonyl chloride to introduce the tosylate (or other sulfonate) functionality to form the corresponding organo tosylate reactant (e.g., 3-methylenepent-4-en-1-yl 4-methylbenzenesulfonate in Example 2 below). The ability to readily synthesize a wide range of organo sulfonates opens this synthetic pathway to synthesis of a corresponding wide range of organotin precursors.

For the reactions described herein, primary R groups (i.e., R groups that have a 1° C. atom that forms the C—Sn bond) can be particularly effective at forming the desired RSn(OR′)₃ compositions via the synthetic routes described herein. In general, R ligands are organo ligands with 1-31 carbon atoms with one or more carbon atoms optionally substituted with one of more heteroatom functional groups, such as, containing O, N, Si, and/or halogen atoms or an alkyl or a cycloalkyl further functionalized with a phenyl or cyano group with optional unsaturated carbon-carbon or heteroatom bonds. In particular, olefinic R ligands having unsaturated carbon bonds can also be prepared, such as R ligands having two or more C═C bonds, as shown in the examples herein.

In some embodiments, the R ligands are fluorinated. Fluorine atoms can be desirable to substitute for H atoms within the R ligands due to their higher EUV absorption. Additionally, the presence of F atoms within the R ligand can increase the hydrophobicity of the ligand, thus in some embodiments improving the developer contrast between irradiated and non-irradiated areas of the film. Applicant has described synthesis of organotin compounds having fluorinated alkenyl ligands in U.S. patent application Ser. No. 18/731,702 to Jilek et al., entitled “Organotin Alkoxides as Precursors for Patterning Compositions with Fluoride Substituents and Carbon-Carbon Double Bonds”, incorporated herein by reference.

The alkali tin trialkoxide intermediate, MSn(OR′)₃, a bimetallic alkoxide of Sn(II), has been discovered to be a useful reagent for forming organotin trialkoxides, and can be prepared according to the following reaction:

SnCl₂+3MOR′\grave{a}MSn(OR′)₃+2MCl (6)

The alkali metal M can generally be chosen from Li, Na, K, Cs, or Rb. In some embodiments, M is K. In some embodiments, M is Li or Na. The MSn(OR′)₃ compound can be isolated, purified, and incorporated as a solid reagent dissolved in appropriate solvents in the syntheses, and its preparation is included in the Examples herein. When reacted with an organohalide or organosulfonate at modest temperatures and conditions, an oxidative addition reaction can occur wherein a carbon tin bond is formed with rapid formation of potassium halide and RSn(OR′)₃. As exemplified below, the reaction is performed in two steps with 2 equivalents of MOR′ added first to precipitate the MCl, which can then be removed. A further amount of MOR′ is added, and a somewhat less than an equivalent can be added in view of losses from the filtering for removal of the precipitated MCl. Generally, the precipitated alkali halide, such as potassium halide, salt can be alternatively filtered away, and/or the RSn(OR′)₃ product can be purified and collected, such as via distillation.

The reactions are generally performed in dry organic solvents under an oxygen free or depleted atmosphere, such as a nitrogen purged atmosphere. Solvents can be selected to result in the solubility of the various components. Due to interactions of the solvent with the metal ions, selection of solvents can be based at least in part on reaction rates in the selected solvents, which can be evaluated empirically. If different solvents are selected, they are generally miscible. Both aprotic polar and non-polar solvents are generally useful, such as alkanes (for example, hexane, pentane), ethers (for example, dimethyl ether, diethyl ether), tetrahydrofuran (THF), acetone, toluene, acetonitrile, and mixtures thereof. The solvents should generally be selected to be inert with respect to the reactants, intermediates, and products. If multiple solvents are used, for example to introduce distinct reactants, the solvents should generally be miscible with respect to each other.

A catalyst comprising a halide can be present during the reaction of the bimetallic MSn(OR′)₃ compound and the alkylhalide or alkylsulfonate RX compound. The catalyst can generally comprise a tetraalkyl (quaternary) ammonium salt, a tetraalkyl phosphonium salt or a mixture thereof, such as tetrabutylammonium iodide, tetrabutylammonium bromide, tetrabutylammonium hexafluorophosphate, and/or tetraphenylphosphonium chloride. Since the catalyst is not consumed, the amount of catalyst can be selected to influence the reaction rate as desired. Generally, the amount of catalyst is a fraction of a stoichiometric amount.

The reactions using MSn(OR′)₃ as a starting material can generally be performed in a single pot without any intermediate steps, such as separation, purification, transfer, and the like. Following the reaction between the bimetallic alkoxide MSn(OR′)₃ and the organohalide or the organotosylate, the desired organotin alkoxide product can be obtained in pure form via filtration and/or distillation, depending on the nature of the product.

The reactions described herein are highly selective towards formation of a mono-organo tin trialkoxide compound, and the organotosylate (or organohalide or other organosulfonate) can generally be present as a reactant in a molar excess of the MSn(OR′)₃ composition. In some embodiments, the organo tosylate can be present up to about 2 mol. equivalents to the MSn(OR′)₃ compound, up to about 1.6 mol. equivalents to the MSn(OR′)₃ (or Sn₂(OR′)₄) compound in other embodiments, up to about 1.3 mol. equivalents MSn(OR′)₃ compound in other embodiments, and up to about 1.1 mol. equivalents to the MSn(OR′)₃ compound in further embodiments. In some embodiments, the organotosylate and the MSn(OR′)₃ compound can be present in roughly stoichiometric amounts. Note with the reactions based on Sn₂(OR′)₄, the generation of an Sn by-product that is removed results in a limit of 50% yield based on tin, which is not a constraint for the reactions involving MSn(OR′)₃ reactant. The reaction is not particularly sensitive to concentrations, although the concentrations should be reasonable and dilute. Thus, in some embodiments, the concentrations for the reactions to form the organotin compounds can be from about 1×10⁻⁵ M to about 0.001M in terms of the tin concentrations. A person of ordinary skill in the art will recognize that additional ranges of relative reactant amounts and concentrations within the explicit ranges above are contemplated and are within the present disclosure.

In some embodiments, the reactions can generally be performed at temperatures less than about 120° C. (such as about 35° C. to about 120° C.), less than about 100° C., less than about 80° C. in other embodiments, and less than 60° C. in further embodiments. In some embodiments, the reactions can be performed at room temperature. In some embodiments, the reaction can be cooled and performed at temperatures from about −80° C. to about −60° C., from about −60° C. to about −40° C. in some embodiments, from about −40° C. to about −20° C. in other embodiments, and from about −20° C. to about 20° C. in other embodiments. The reactions are generally stirred for the duration of the reaction. Efficacy of the reaction can be monitored by analyzing the reaction mixture via ¹H and/or ¹¹⁹Sn NMR to determine when the reaction has reached sufficient completion. In some embodiments, the reactions can be performed for about 5 days, for about 3 days in other embodiments, for about 1 day in other embodiments, for about 12 hours, and for about 1 hour in further embodiments. A person of ordinary skill in the art will recognize that additional ranges of time and temperature within the explicit ranges above are contemplated and are within the present disclosure. Desirable reaction times and temperatures can generally depend on the identity of the organohalide (RX), the organomesylate, the organotosylate (RY), or other organosulfonate. Reactivity of the organohalide generally follows in the order of X═I>Br>Cl, and in the order of the carbon forming the C—X bond as 1°>2°>>3°. Suitable reaction times and temperatures can be determined through routine experimentation based on the teachings herein. The reactions are generally performed under an inert atmosphere, such as N₂ or Ar. A person of ordinary skill in the art will recognize that additional ranges of process conditions within the explicit ranges above are contemplated and are within the present disclosure.

Once the product is formed, the organotin trialkoxides can be purified. The purification depends on the nature of the product, but generally involves the separation of the desired product from by products and potentially any unreacted reagents. Purification can generally be achieved by methods known in the art. Typical means of purification can comprise filtration, recrystallization, extraction, distillation, sublimation, combinations thereof, and the like. Filtration is typically performed on a crude product mixture using commercial filters to remove insoluble contaminants and/or by products, for example, metal halide salts such as KI, from the solution containing the desired product. Recrystallization methods can be useful to purify solid compounds by forming, via heating, a saturated solution that then is allowed to cool. Extraction techniques can comprise, for example, liquid-liquid extractions wherein two non-miscible solvents with different densities are used to separate the desired compounds based on their relative solubilities. Purification can also comprise removal of any volatile compounds including solvents from the product mixture by drying with heat and/or exposure to vacuum. For products with significant vapor pressures, it can be desirable to purify the product through vacuum distillation or, if desired, fractional distillation designed to achieve high purity. See published U.S. patent application 2020/0241413 to Clark et al., entitled “Monoalkyl Tin Trialkoxides and/or Monoalkyl Tin Triamides With Low Metal Contamination and/or Particulate Contamination and Corresponding Methods,” incorporated herein by reference. In some embodiments, purification of a ditin compound can be performed via sublimation.

The organotin trialkoxides, RSnL₃ (L=OR′), described herein can be further processed to form corresponding organotin compounds with different hydrolysable ligands, L. In one example, the alkoxide ligands can be replaced with different alkoxide ligands, such as replacing one or more OR′ ligands for OR″ ligands via solvolysis and/or alcoholysis. The organotin trialkoxides can also be converted to organotin triamides (RSnL₃, L=NR″₂), such as via reaction of the organotin trialkoxide with LiNR″₂ or similar metal amide, where R″ are independently organo groups with 1-10 carbon atoms. Suitable triamides can be, for example, RSn(NMe₂)₃ or RSn(N(SiR′₃)₂)₃, where R′ is an organo group with 1-5 carbon atoms. In other examples, the alkoxide ligands can be replaced by acetylide, amidinate, carboxylate, and so forth.

The hydrolysable ligand can generally be chosen for handling or use-case considerations, such as for use in a desired mode of processing the RSnL₃ composition into a radiation patternable film. For example, while organotin trialkoxides (RSn(OR′)₃, L=OR′) can be desirable for the formation of resist solutions, organotin triamides (RSn(NR″₂)₃) can be particularly desirable for use vapor deposition applications because of their generally high vapor pressures and high reactivity. In either case, i.e. L=OR′ or L=NR″, the hydrolysis and condensation reactions that occur during the deposition process result in the formation of similar organotin oxide hydroxide film compositions wherein the Sn—C bonds are conserved and Sn—O—Sn and Sn—OH bonds are formed from hydrolysis of the Sn-L bonds.

### Precursor Solutions, Coatings, Deposition, and Related Compositions:

The organotin precursor compositions described herein can be effectively used for radiation patterning, especially EUV patterning. The ability to have greater flexibility for R ligand selection allows for further improvements in patterning results as well as designing ligands to be particularly effective for specific applications. In general, any suitable coating process can be used to deliver the precursor solution to a substrate. Suitable coating approaches can include, for example, solution deposition techniques such as spin coating, spray coating, dip coating, knife edge coating, printing, such as inkjet printing and screen printing, and the like. Many of the precursors are also suitable for vapor deposition onto a substrate as discussed in the '618 patent cited above. For some R ligand compositions and/or specific process considerations, vapor deposition may be useful for preparation of radiation sensitive coatings.

After preparation of the desired organotin precursor, the precursor can be dissolved in an appropriate solvent to prepare a precursor solution, such as an organic solvent, e.g., alcohols, aromatic and aliphatic hydrocarbons, esters or combinations thereof. In particular, suitable solvents include, for example, aromatic compounds (e.g., xylenes, toluene), ethers (anisole, tetrahydrofuran, propylene glycol methyl ether), esters (propylene glycol monomethyl ether acetate, ethyl acetate, ethyl lactate), alcohols (e.g., 4-methyl-2-pentanol, 1-pentanol, 1-butanol, methanol, isopropyl alcohol, 1-propanol), ketones (e.g., methyl ethyl ketone), mixtures thereof, and the like. In general, organic solvent selection can be influenced by solubility parameters, volatility, flammability, toxicity, viscosity and potential chemical interactions with other processing materials.

The organotin precursor(s) can also generally be dissolved in mixtures of solvents to prepare precursor solutions. Some solvent mixtures useful for forming organotin photoresist solutions have been described in published U.S. Patent Application 2023/0143592 to Jiang et al., entitled “Stability-Enhanced Organotin Photoresist Compositions”, incorporated herein by reference. It can be desirable for the organotin precursor(s) to be dissolved in a solvent mixture comprising a primary alcohol. In some embodiments, the solvent can comprise a primary alcohol, such as methanol, ethanol, 1-propanol, 1-butanol, 1-pentanol, 1-hexanol, and the like. In some embodiments, the solvent can comprise a mixture of two alcohols. In other embodiments the solvent can comprise a mixture of an alcohol and an ester. In other embodiments, such as exemplified in Example 4, the solvent can comprise a mixture of a solvent, such as an alcohol and a controlled amount of water. In particular, the water level can be adjusted, generally by addition of small amounts of water to the solvent. to achieve the target water levels, generally no more than about 10,000 ppm by weight, in further embodiments from about 200 ppm to about 5000 ppm and in additional embodiments from about 300 ppm by weight to about 2500 ppm by weight. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference. After the components of the solution are dissolved and combined, the character of the species may change as a result of partial in-situ hydrolysis, hydration, and/or condensation.

The organotin precursors can be dissolved in the solvent at concentrations to afford concentrations of Sn suitable for forming coatings of appropriate thickness for processing. In general, the precursor solutions comprise one or more organotin compositions, such as RₙSnL₄₋ₙ and its hydrolysates, where R is chosen from the various moieties described in detail herein and L is a hydrolysable ligand. The concentrations of the species in the precursor solutions can be selected to achieve desired physical properties of the solution. In particular, lower concentrations overall can result in desirable properties of the solution for certain coating approaches, such as spin coating, that can achieve thinner coatings using reasonable coating parameters. It can be desirable to use thinner coatings to achieve ultrafine patterning as well as to reduce material costs. In general, the concentration can be selected to be appropriate for the selected coating approach. Coating properties are described further below. In general, tin concentrations comprise from about 0.005M to about 1.4M, in further embodiments from about 0.02 M to about 1.2 M, and in additional embodiments from about 0.1 M to about 1.0 M. A person of ordinary skill in the art will recognize that additional ranges of tin concentrations within the explicit ranges above are contemplated and are within the present disclosure.

Control over the polymerization process that leads to crosslinking of the diene ligands can be achieved by including polymerization inhibitors and/or providing a blend of precursors in the organotin precursor composition. In either case, the availability of more extensive crosslinking is limited. Thus, in some embodiments, the organotin precursor composition comprising diene ligands can further comprise a polymerization inhibitor, such as a radical scavenger since polymerization is believed to occur with a radical polymerization mechanism. Below, the use of precursor blends is described. Appropriate polymerization inhibitor compounds can effectively inhibit or mitigate the initiation or propagation step of the free radical polymerization process, thereby preventing the film from undergoing extended crosslinking and polymerization. In some embodiments, the polymerization inhibitor compounds can be selected to decompose and/or volatilize during specific steps of the lithographic process, such as during a thermal bake step. After volatilizing the polymerization inhibitors, the film is no longer stabilized against extended crosslinking and polymerization can occur.

Suitable polymerization inhibitors can include radical scavengers and other compounds that can deactivate, inhibit, scavenge, or otherwise consume radicals or other species responsible for initiating or propagating polymerization reactions between diene ligands. In some embodiments, the polymerization inhibitor is selected from 4-tert-butyl catechol, butylated hydroxy toluene (BHT), TEMPO, 4-hydroxy-TEMPO, and mequinol (4-methoxyphenol). Additional polymerization inhibitors can include the radical scavengers described in U.S. patent application Ser. No. 19/042,239 entitled “Radical Trapping Additives for Metal Oxide Resists”, by Eberle et al., incorporated herein by reference.

In an Example below, the inclusion of a radical scavenger in the diene-ligand organotin composition is seen to suppress the organic polymerization of the organotin composition, allowing for the formation of oxo-hydroxo rich networks in the films, such as in RSnOOH, (RSn)₁₂O₁₄(OH)₈, and related compounds, which can otherwise be inhibited due to extensive organic crosslinking. The ability to fine-tune the degree of crosslinking through the choice of diene ligand structure, polymerization inhibitor, and processing conditions provides for flexibility in adjusting resist performance for specific applications. The concentration of a polymerization inhibitor can be influenced by the specific polymerization inhibitor compound. Generally, the precursor solution can have a concentration polymerization inhibitor from about 0.00005M to about 0.25M, in further embodiments from about 0.0001M to about 0.125M, and in other embodiments from about 0.00025M to about 0.1M. The concentration of polymerization inhibitor can be expressed as a molar ratio of the polymerization inhibitor molarity divided by the tin concentration, and expressed as a ratio, the polymerization inhibitor concentration can be at least 1%, in further embodiments from about 2% to about 100%, and in other embodiments from about 2.5% to about 50% of the tin concentration. A person of ordinary skill in the art will recognize that additional ranges of polymerization inhibitor concentration within the explicit ranges above are contemplated and are within the present disclosure. The relative amounts of diene ligands in a blended precursor solution may influence selection of a concentration of a polymerization inhibitor for inclusion in a blended precursor solution. The relative concentrations can be selected consistent with the teachings above.

In some embodiments, improved photosensitive precursor compositions can be present in a blended solution with two or more organotin compositions, such as RₙSnL₄₋ₙ and its hydrolysates, where the two or more R ligands are chosen from the various moieties described in detail herein with at least one of the R ligands being a polyene, such as a diene. Such blended solutions can be tuned for selection of various performance considerations, such as solution stability, coating uniformity, film solubility, and patterning performance. In some embodiments, as demonstrated in Example 5, a blended solution with a first organotin composition having an R comprising a diene and a second organotin composition having an R without a diene can be used to modulate the solubility of resulting films to developer solutions, as compared to a film formed from the second organotin composition alone. In some embodiments, the improved photosensitive composition can comprise at least 0.1% by mole Sn of a desired component in the blended solution, in further embodiments at least 0.25% by mole Sn of the blended solution, in further embodiments at least 0.5% by mole Sn of the blended solution, and in further embodiments at least 1% by mole Sn of a specific desired component of the blended solution. In general, the upper limit of a component of a blend is set by the amount of other components. The blended precursors generally comprise at least about 0.25% by mole Sn of polyene, e.g. diene, containing precursors, in further embodiments from about 0.4% by mole Sn to about 20% by mole Sn and in other embodiments from about 0.5% by mole Sn to about 12% by mole Sn of diene containing precursors relative to the total molar amount of Sn. Additional ranges of mol % of the improved photosensitive composition within the explicit ranges of the blended solution are contemplated and within the present disclosure. The hydrolysable ligands L can be hydrolyzed during deposition or following deposition, such as through hydrolysis with water vapor.

Owing generally to their suitable vapor pressures, the organotin compositions described herein can be useful as precursors for forming coatings via vapor deposition. Vapor deposition methods generally include chemical vapor deposition (CVD), physical vapor deposition (PVD), atomic layer deposition (ALD), and modifications thereof. In a typical vapor deposition process, the organotin composition can be reacted with small molecule gas-phase reagents such as H₂O, O₂, H₂O₂, O₃, CH₃OH, HCOOH, CH₃COOH, and the like, which serve as O and H sources for production of radiation sensitive organotin oxide and oxide hydroxide coatings. Water vapor can be provided from ambient air, delivered in vapor form, or otherwise provided in a suitable liquid or vapor composition. Specific apparatuses for vapor deposition of radiation patternable organotin coatings has been described by Wu et. al in PCT Application #PCT/US2019/031618 entitled “Methods for Making EUV Patternable Hard Masks”, incorporated herein by reference. Production of radiation sensitive organotin coatings can generally be achieved by reacting the volatile organotin precursor RSnL₃ with a small gas-phase molecule. The reactions can include hydrolysis/condensation of the organotin precursor to hydrolyze the hydrolysable ligands while leaving the Sn—C bonds substantially intact. In some embodiments, two or more distinct RSnL₃ compounds having different R and/or L ligands can be used to form a final film that comprises a mixture of the RSn species. As shown in the Examples, conjugated olefinic R groups can be useful in such a blended film.

Whether deposited by solution deposition or vapor deposition, hydrolysis of the hydrolysable ligands can result in formation of an oxo-hydroxo network represented by RSnOₓ(OH)₃₋₂ₓ. Generally, radiation exposure and patterning is performed with the hydrolyzed coating.

The crosslinking mechanisms provided by the diene ligands offers a further improvement to the organotin photoresist material by reducing the amount of shrinkage during processing. In conventional organotin photoresist materials, exposure of the material to radiation results in the cleavage of the Sn—C bonds that bind the organo groups to the Sn atoms and the subsequent release of volatile organic material from the material. After volatilizing and removal of the organic content of the film, the Sn centers are no longer stabilized against condensation which promotes formation of polynuclear metal oxo-hydroxo bonds that ultimately provide for a denser metal oxide hydroxide network. The molecular volume once occupied by the organo ligands is removed and the Sn centers are better able to condense together in space, and therefore exposed material can shrink during the post-irradiation processing of the film, e.g., heating.

Shrinkage of patterns can make it challenging to predict and control the pattern's critical dimension (CD). In general, organotin resists operate through Sn—C bond cleavage, which removes organic material from the film and allows the material to condense/densify during a post-exposure heating step. This condensation and densification process can lead to substantial shrinkage, which can negatively impact pattern fidelity and defectivity. The amount of shrinkage can depend on factors such as the size and structure of the organo groups, the degree of crosslinking in the initial film, and the processing conditions.

The diene ligands described herein allow for thermal and/or radiation-induced crosslinking between Sn—R groups to form a Sn—R^{c}—R^{c}—Sn network, wherein R^{c} represents the crosslinked R group. The crosslinked R groups, R^{c}—R^{c}, form a new structure that can be considered a bridging ligand having Sn—C bonds wherein two Sn atoms are connected through a shared organo ligand. The exposed film therefore substantially retains the organic content of the film while rendering the material insoluble in developer. The crosslinked organic moieties remain in the film, preventing the Sn centers from condensing and densifying to form a metal oxide. In this way, shrinkage of the patterned material can be reduced.

With respect to an outline of a representative process for a radiation-based patterning, e.g., an extreme ultraviolet (EUV) lithographic process, photoresist material is deposited or coated as a thin film on a substrate, subjected to a post-application bake (PAB), exposed with a pattern of radiation to create a latent image, subjected to a post-exposure bake (PEB), and then developed with a solution-based process or a gas-based process, to produce a developed pattern of the resist. Fewer steps can be used if desired, and additional steps can be used to remove residue to improve pattern fidelity.

The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 1 nm to 50 nm, and in further embodiments from about 1 nm to 25 nm. Those of ordinary skill in the art will understand that additional ranges of coating thickness are contemplated and are within the present disclosure.

Coating thickness for radiation patternable coatings prepared by vapor deposition techniques can generally be controlled through appropriate selection of reaction time or cycles of the process. The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 1 nm to 50 nm, from about 1 nm to about 40 nm, from about 1 nm to about 25 nm, and in further embodiments from about 2 nm to about 25 nm. Those of ordinary skill in the art will understand that additional ranges of coating thickness are contemplated and are within the present disclosure.

The substrate generally presents a surface onto which the coating material can be deposited, and it may comprise a plurality of layers in which the surface relates to an upper most layer. The substrate is not particularly limited and can comprise any reasonable material such as silicon, silica, other inorganic materials, such as ceramics, and polymer materials.

After deposition and formation of the radiation patternable coating, further processing can be employed prior to exposure with radiation. In some embodiments, the coating can be heated from between 30° C. and 300° C., in further embodiments from between 50° C. and 200° C., and in further embodiments from between 80° C. and 150° C. The heating can be performed, in some embodiments for about 10 seconds to about 10 minutes, in further embodiments from about 30 seconds to about 5 minutes, and in further embodiments from about 45 seconds to about 2 minutes. The heating may be performed in air, vacuum, or an inert gas ambient, such as Ar or N₂, and the heating can be divided into segments optionally with different temperatures and/or different gas composition and/or pressures. Additional ranges for temperatures and heating durations within the above explicit ranges are anticipated and envisioned. In other embodiments, as shown in the Examples, the as-deposited coatings can be poised for further processing without a post-apply bake (PAB).

### Patterning of the Compositions:

Radiation generally can be directed to the coated substrate through a mask or a radiation beam can be controllably scanned across the substrate. In general, the radiation can comprise electromagnetic radiation, an electron-beam (beta radiation), or other suitable radiation. In general, electromagnetic radiation can have a desired wavelength or range of wavelengths, such as visible radiation, ultraviolet radiation, or X-ray radiation. The resolution achievable for the radiation pattern is generally dependent on the radiation wavelength, and a higher resolution pattern generally can be achieved with shorter wavelength radiation. Thus, it can be desirable to use ultraviolet light, X-ray radiation, or an electron-beam to achieve particularly high-resolution patterns. In general, the organotin patterning compositions developed by Applicant are suitable for either positive tone or negative tone patterning, although ultimate patterning performance for either tone can depend on selection of the organo ligands since either patterning tone requires different material considerations, such as solubility, polarity, density, and so forth. For example, an organotin compositions having a given R group does not necessarily pattern with equal capabilities (e.g., contrast) in both patterning tones, though both positive tone and negative tone patterning are broadly enabled by the properties of organotin oxide hydroxide films. As further embodiments have been explored of the compositions and processing, approaches have been developed to enhance one tone of processing over the other. The various ligands and combinations thereof described herein provide additional options for design of radiative patterning film compositions that can be explored for desirable patterning with particular objectives.

In general, while suitable radiation sources are those that generally provide for wavelengths that effectively absorb in the photoresist, typical radiation sources generally correspond to commercial lithography applications. For example, wavelengths most relevant to lithography include commercial EUV exposure tools (such as those fabricated by ASML) which operate at a wavelength of 13.5 nm and commercial UV exposure tools which generally operate at a wavelength of 193 nm for ArF excimer laser sources or 248 nm for KrF excimer laser sources. A person of ordinary skill in the art will understand that other absorbative wavelengths are contemplated and within the scope of the disclosure. The international standard for optics and photonics is ISO 20473:2007(E), incorporated herein by reference. This standard has the broad range of UV wavelengths from 1 nm to 380 nm, with the EUV range from 1 nm to 100 nm.

Based on the design of the coating material, there can be a large contrast of material properties between the irradiated regions that have condensed coating material and the unirradiated, coating material with substantially intact Sn—C bonds. For embodiments in which a post irradiation heat treatment (i.e., a post-exposure bake, PEB) is used, the post-irradiation heat treatment can be performed at temperatures from about 45° C. to about 250° C., in additional embodiments from about 50° C. to about 190° C. and in further embodiments from about 60° C. to about 175° C. The post exposure heating can generally be performed for at least about 0.1 minute, in further embodiments from about 0.5 minutes to about 30 minutes and in additional embodiments from about 0.75 minutes to about 10 minutes. The heating may be performed in air, vacuum, or an inert gas ambient, such as Ar or N₂, and the heating can be divided into segments optionally with different temperatures and/or different gas composition and/or pressures. A person of ordinary skill in the art will recognize that additional ranges of post-irradiation heating temperature and times within the explicit ranges above are contemplated and are within the present disclosure. This high contrast in material properties further facilitates the formation of high-resolution lines with smooth edges in the pattern following development as described in the following section.

For positive-tone implementations, the photoresist increases solubility in appropriate aqueous solvents after exposure to radiation. The organotin compositions having diene ligands can polymerize to form insoluble films at deposition and/or with mild heating. To facilitate positive-tone patterning, it can be desirable to design the photoresist composition to undergo depolymerization and/or to undergo a polarity switch during exposure. Polymerization inhibitors can be used to control the degree of polymerization and corresponding solubility properties at various stages of processing. in the context of precursor blends, ligands having tertiary alpha carbons, such as tert-butyl, have been shown to undergo Sn—C bond cleavage more readily (i.e., requires less exposure dose and/or lower temperatures) than ligands having primary alpha carbons, such as n-butyl. The stability of the Sn—C bond with respect to radiation and heating can be referred to as the bond dissociation energy (BDE) of the Sn—C bond. While not wanting to be limited by theory, it is believed that the BDE of the Sn—C bond is correlated with the cleaved ligand's radical and/or carbocation stability. Tertiary radicals and carbocations are generally more stable than secondary which are generally more stable than primary. Therefore, the bond dissociation energy of the Sn—R bond (and therefore the energy dose and/or temperature required to cleave the bond) can be reduced by modifying the R ligand to include a tertiary alpha carbon.

The polymerization process affords an insoluble crosslinked material that resists removal by developer. If radiation induced scission of the polymer takes place, the molecular weight of the polymer moiety is reduced, the solubility in developer increases. Additionally, the radiation-induced cleavage of the Sn—C bonds results in the formation of polar species comprising Sn—OH and Sn—O bonds, and these polar species can be further promoted during post-exposure heating processes as the exposed material reacts with ambient air and humidity. The formation of polar species can further increase the solubility of the exposed material in a suitable polar developer, such as an aqueous base.

Inclusion of the heteroatoms such as O and S in the diene ligand can improve the hydrophilicity of the polymerized films while not necessarily increasing their solubility which is beneficial for positive-tone development with an aqueous developer. The increase in hydrophilicity associated with the inclusion of O and S heteroatoms, such as in the furan and thiophene structures above, can improve the wettability and surface interaction of the developer liquid with the photoresist material. The improved wettability allows for better cross-wafer uniformity of the development process.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, alcohols (e.g., 4-methyl-2-pentanol, 1-butanol, isopropanol, 1-propanol, methanol), ethyl lactate, ethers (e.g., tetrahydrofuran, dioxane, anisole), esters (propylene glycol monomethyl ether acetate, ethyl acetate, ethyl lactate), ketones (pentanone, hexanone, 2-heptanone, octanone), and the like, and mixtures thereof. To aid development, the developer can further include organic acids such as formic acid, acetic acid, and other carboxylic acids. Suitable developers are further described in published U.S. Patent Application No. 2020/0326627 to Jiang et. al, entitled “Organometallic photoresist developer compositions and processing methods”, incorporated herein by reference, and such developers may generally include solvent blends of ketone, alcohol, ether, ester and water, glycol ether, pyrrolidone, lactone, carboxylic acid, or combinations thereof. The development can be performed for about 5 seconds to about 30 minutes, in further embodiments from about 8 seconds to about 15 minutes and in additional embodiments from about 10 seconds to about 10 minutes. A person of ordinary skill in the art will recognize that additional ranges within the explicit ranges above are contemplated and are within the present disclosure.

With a weaker developer, e.g., diluted organic developer or compositions in which the coating has a lower development rate, a higher temperature development process can be used to increase the rate of the process. With a stronger developer, the temperature of the development process can be lower to reduce the rate and/or control the kinetics of the development. In general, the temperature of the development can be adjusted between the appropriate values consistent with the volatility of the solvents. Additionally, developer with dissolved coating material near the developer-coating interface can be dispersed with ultrasonication during development. The developer can be applied to the patterned coating material using any reasonable approach. For example, the developer can be sprayed onto the patterned coating material. Also, spin coating can be used. For automated processing, a puddle method can be used involving the pouring of the developer onto the coating material in a stationary format. If desired spin rinsing and/or drying can be used to complete the development process. Suitable rinsing solutions include, for example, ultrapure water, aqueous tetraalkyl ammonium hydroxide, methyl alcohol, ethyl alcohol, propyl alcohol and combinations thereof. After the image is developed, the coating material is disposed on the substrate as a pattern.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant that facilitates removal of irradiated or non-irradiated regions. Dry development can also be based on halide chemistries, as described by Tan et. al in PCT Pat App. No: PCT/US2020/039615 entitled “Photoresist Development With Halide Chemistries”, incorporated herein by reference. For organotin photoresist coatings, dry development can be conducted through the use of halogen-containing plasmas and gases, for example HBr and BCl₃. In some cases, dry development may offer advantages over wet development such as reduced pattern collapse, deceased scum, and fine control over developer compositions, i.e. the plasma and/or etch gases. See also, published U.S. patent application 2023/0408916 to De Schepper et al., entitled “Gas-Based Development of Organometallic Resist in an Oxidizing Halogen-Donating Environment,” incorporated herein by reference. Following development, a rinse step can be conducted if desired to further remove undesired material from the pattern, and such methods have been described in published U.S. Patent Application No. 2020/0124970 to Kocsis et al., entitled “Patterned Organometallic Photoresists and Methods of Patterning,” incorporated herein by reference.

After completion of the development step, the coating materials can be heat treated to further condense the material and to further dehydrate, densify, or remove residual developer from the material. This heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂, and the heating can be divided into segments optionally with different temperatures and/or different gas composition and/or pressures. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

### EXAMPLES

### Example 1. Synthesis of potassium tris(tert-butyl oxide)tin (KSn(OtBu)₃)

This example describes a method for the synthesis of potassium tri(tert-butyl oxide)tin. The method is based on the following reaction.

SnCl₂+K(OtBu)→KSn(OtBu)₃

Tin dichloride and anhydrous tetrahydrofuran were added to a reaction vessel under inert atmosphere to form a solution having a concentration of approximately 0.07 g SnCl₂/ml THF. The solution was mixed while cooling to 4° C. Then 2.0 molar equivalents of potassium tert-butyl oxide relative to the initial tin dichloride amount was added slowly. The reaction mixture was maintained at a temperature below 60° C. Upon completion of the addition step, the reaction mixture was stirred for approximately 1 hour. The resulting white precipitate was removed by filtration over a bed of celite and the filtrate was collected. Additional potassium tert-butyl oxide (0.9 molar equivalents relative to the initial tin dichloride amount) was added slowly to the filtrate. In view of processing practicalities, the 0.9 molar equivalents relative to initial tin is roughly a molar equivalent relative to persistent tin. The reaction mixture was maintained at a temperature below 60° C. Volatiles were removed under vacuum and the product was recrystallized from a 1:1 mixture of THF/Toluene (˜2 mL/g product) at −20° C. to afford KSn(OtBu)₃ as a white crystalline solid.

This example demonstrates a method for synthesizing potassium tri(tert-butyl oxide)tin, which is used in Examples 2 and 3.

### Example 2. Synthesis of 3-methylene-pent-4-en-yltin tris(tert-butyl oxide) (EBDSn(OtBu)₃)

This example describes a method for the one-pot, direct synthesis of the diene-containing organotin trialkoxide (“EBDSn(OtBu)₃”) represented by Formula 1. The method is based on the following reaction.

KSn(OtBu)₃+CH₂CHC(CH₂)(CH₂CH₂)—O—SO₂—C₆H₄—CH₃→CH₂CHC(CH₂)(CH₂CH₂)Sn(OtBu)₃

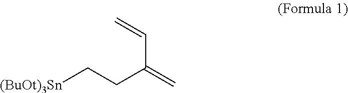

The reagent CH₂CHC(CH₂)(CH₂CH₂)—O—SO₂—C₆H₄—CH₃ was synthesized in-house starting from reaction of 4-oxotetrahydro pyran with a Wittig reagent to form 4-methylidenetetrahydro pyran following methods described in Angew. Chem., Int. Ed., 2021, 60, 11763-11768, incorporated herein by reference. The 4-methylidenetetrahydro pyran was then subjected to a ring opening reaction with lithium diisopropyl amide/potassium tert-butoxide with subsequent tosylation using methods described in J. Am. Chem. Soc. 2005, 127, 49, 17433-17438, incorporated herein by reference, to form CH₂CHC(CH₂)(CH₂CH₂)—O—SO₂—C₆H₄—CH₃.

The KSn(OtBu)₃ product from Example 1, 0.6 molar equivalents (referenced to 1 molar equivalent of tin) of tetrabutylammonium iodide ((n-Bu)₄N(I)) as a catalyst, and toluene were added to a reaction vessel under inert atmosphere and mixed to form a solution having a concentration of approximately 0.05 g KSn(OtBu)₃/ml toluene. The solution was mixed at room temperature. Then 1.2 molar equivalents of 3-methylene-pent-4-en-yltosylate (CH₂CHC(CH₂)(CH₂CH₂)—O—SO₂—C₆H₄—CH₃) relative to the KSn(OtBu)₃ amount was added slowly with stirring. Then the reaction mixture was heated to 80° C. and stirred for 1 day. Afterwards, volatiles were removed under vacuum and the remaining residue was filtered over a bed of celite with pentane. The filtrate was pumped down and distilled to obtain a white solid following solidification of the distillate.

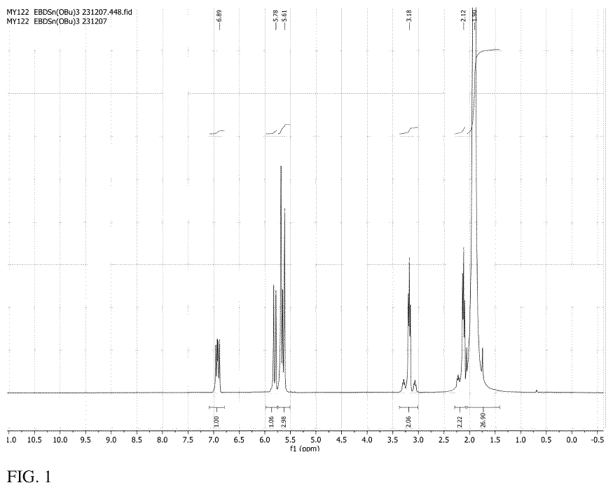

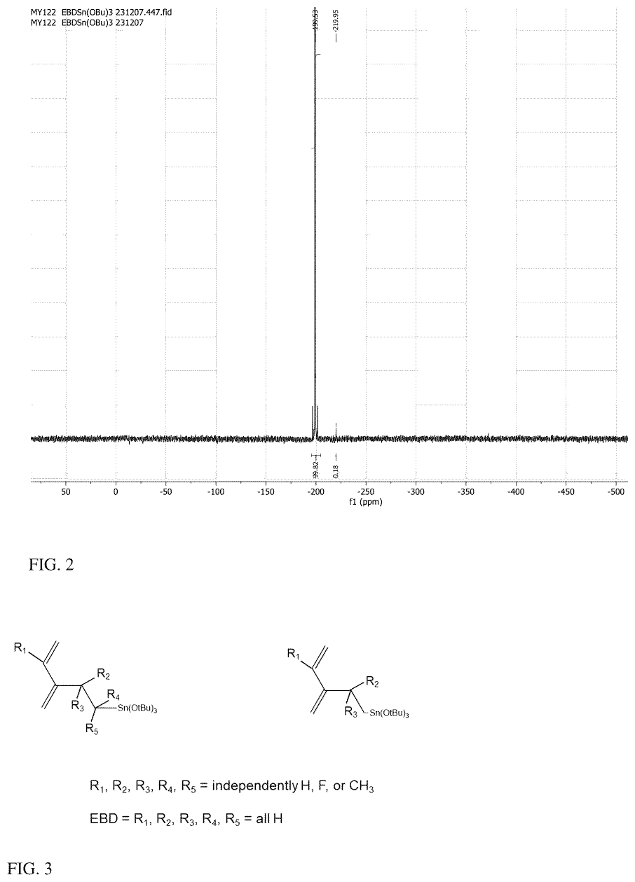

FIG. 1 is the ¹H NMR spectrum of the product CH₂CHC(CH₂)(CH₂CH₂Sn(OtBu)₃, which shows the following chemical shifts: ¹H NMR (400 MHz, C₆D₆) δ 1.43 (s, 27H), 1.54 (t, 2H), 2.65 (t, 2H), 4.95+4.98 (m, 3H), 6.27 (dd, 1H) ppm. FIG. 2 is the ¹¹⁹Sn NMR (149 MHz, neat) spectrum of the product CH₂CHC(CH₂)(CH₂CH₂)Sn(OtBu)₃, which shows a major product at δ −199.5 ppm integrating to 99.82 and a minor impurity at δ −220 ppm integrating to 0.18, indicating a high-purity compound.

A reaction similar to the one described above was performed with EBD bromide instead of EBD tosylate. While the EBD bromide reagent also provided the target product, the EBD bromide reagent was found to be difficult to purify compared to the EBD tosylate reagent. In comparison, the purity of the product was higher with the use of the EBD tosylate reagent while the yield was higher with the use of the EBD bromide reagent. Other experiments, such as presented in Example 3, have shown that the general reaction KSn(OR′)₃+R—X—>RSn(OR′)₃+KX is versatile and robust with respect to the R ligand and the X ligand, see also the '658 application for discussion of products formed with halide X reactants. Products having other R ligands with primary C—Sn bonds and fluorinated ligands have been prepared via this general reaction. The general reaction has been performed with other X ligands, such as Cl, I, and Br, and mesylate (—SO₃CH₃) is known in the art to be generally interchangeable with tosylate. FIG. 3 shows examples of various precursors available via the disclosed methods.

This example describes a method for directly synthesizing a diene-containing organotin trialkoxide with high mono-organo specificity using a diene(tosylate) reactant.

### Example 3. Synthesis of Cyclic Diene-Containing Organotin Trialkoxides

This example describes a method for the direct synthesis and purification of two cyclic diene-containing organotin trialkoxides.

### Part A. Synthesis of (furan-3-yl) methyl tin tris(tert-butyl oxide) (methylfuranyl Sn(O^{t}Bu)₃)

Part A describes a method for the direct synthesis and purification of methylfuranyl Sn(O^{t}Bu)₃, represented by Formula 2.

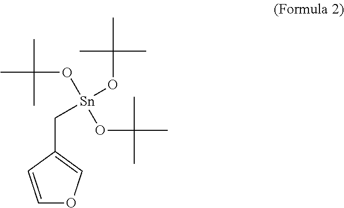 [SMILES: CC(C)(C)[O][Sn]([CH2]c1ccoc1)([O]C(C)(C)C)[O]C(C)(C)C]

The method is based on the following double displacement reaction:

KSn(OtBu)₃+(C₄H₃O)CH₂Br→(C₄H₃O)CH₂Sn(OtBu)₃+KBr

The KSn(OtBu)₃ product from Example 1, 0.2 molar equivalents (referenced to 1 molar equivalent of tin) of tetrabutylammonium iodide ((n-Bu)₄N(I)) as a catalyst, and toluene were added to a reaction vessel under inert atmosphere and mixed to form a solution having a concentration of approximately 0.1 g KSn(OtBu)₃/ml toluene. The solution was mixed at room temperature. Then, 1.2 molar equivalents of 3-(bromomethyl)-furan ((C₄H₃O)CH₂Br) relative to the KSn(OtBu)₃ amount was added slowly with stirring. Then the reaction mixture was heated to 50° C. and stirred for 3 hours. Afterwards, volatiles were removed under vacuum and the remaining residue was filtered over a bed of celite with pentane. The filtrate was pumped down and subsequently distilled to yield a colorless oil of the title compound.

Proton nuclear magnetic resonance (¹H NMR) spectroscopy was performed in C₆D₆ at 400 MHz to characterize the product and showed the following chemical shifts: δ 1.38 (s, 27H), 2.31 (s, 2H), 6.27 (s, 1H), 7.03 (s, 1H), 7.13 (s, 1H). Furthermore, tin NMR (¹¹⁹Sn NMR) was performed with the neat product to show a single peak at δ −224 ppm, indicating a high purity compound.

### Part B. Synthesis of (thiophen-3-yl) methyl tin tris(tert-butyl oxide) (methylthiophenyl Sn(O^{t}Bu)₃)

Part B describes a method for the direct synthesis and purification of methylthiophenyl Sn(O^{t}Bu)₃, represented by Formula 3.

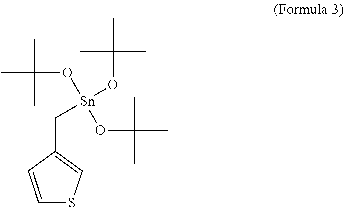 [SMILES: CC(C)(C)[O][Sn]([CH2]c1ccsc1)([O]C(C)(C)C)[O]C(C)(C)C]

The method described in Part A of this Example was followed with the exception that the reaction was performed with 3-(bromomethyl)-thiophene instead of 3-(bromomethyl)-furan and used 0.1 molar equivalents of tetrabutylammonium iodide (referenced to 1 molar equivalent of tin) instead of 0.2 molar equivalents. A colorless oil product of the title compound was obtained after the distillation step. The product was characterized in C₆D₆ using ¹H NMR at 400 MHz and showed the following chemical shifts: δ 1.34 (s, 27H), 2.61 (s, 2H), 6.69 (s, 1H), 6.85 (m, 1H), 6.87 (m, 1H). ¹¹⁹Sn NMR was performed with the neat product, showing a single peak at δ −231 ppm, indicating a high purity compound.

This example describes methods for directly synthesizing cyclic diene-containing organotin trialkoxides with high mono-organo specificity using a methyl furan reactant or a methyl thiophene reactant.

### Example 4: Resist Coating with Diene-Containing Precursors and FTIR and GC-MS Analysis of Films

This example demonstrates the formation of and baking temperature effects on films prepared with the EBDSn(OtBu)₃ product of Example 2 (precursor A). A comparison is made to films prepared with 2-methyl-4-pentenylSn(OtBu)₃ (precursor B).

### Precursor A

An appropriate amount of the EBDSn(OtBu)₃ product of Example 2 was dissolved into 1-propanol containing 1000 ppm H₂O to prepare a coating solution having a tin concentration of 0.05 M. A film coating was then prepared by spin-coating the solution onto a silicon wafer (4-inch diameter FTIR grade, undoped). The solution was dispensed onto the wafer via a syringe equipped with a 0.45-micron filter. The wafer was spun at 1500 rpm for 45 seconds and the resulting film had a thickness of 36.5 nm+/−0.3 nm as measured via ellipsometry.

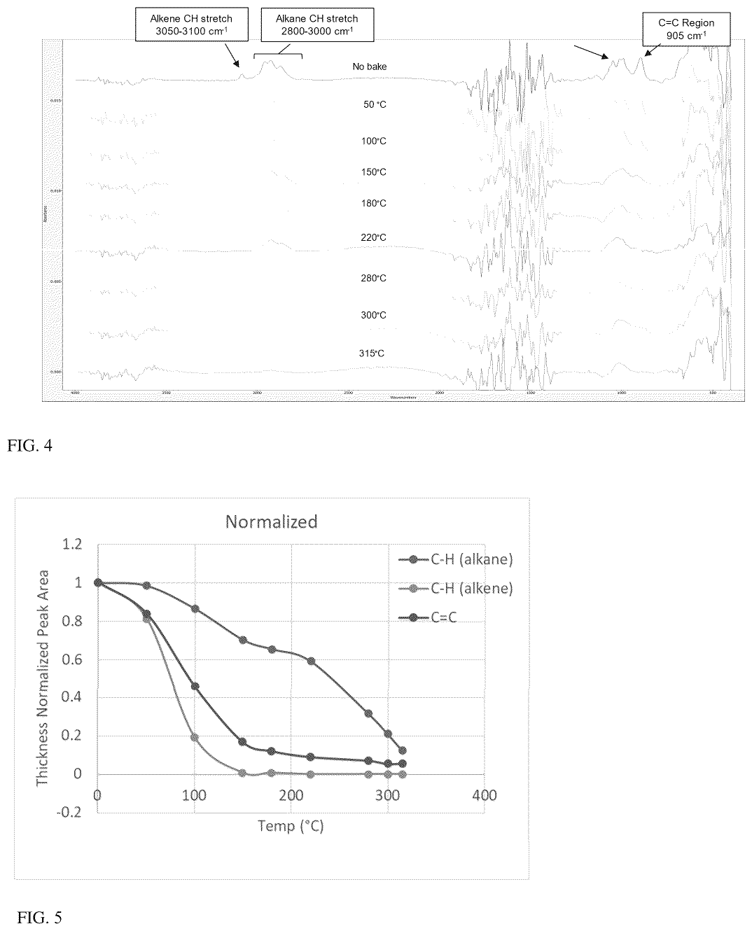

Following deposition of the film, the wafer was cleaved into approximately 1-inch coupons to provide a set of films. Each film was then baked in air at various temperatures ranging from 50° C. to 315° C. for 2 minutes. After completion of the baking process, each film was then analyzed via FTIR, and the results are shown in FIG. 4. An alkene C—H stretch region can be assigned to wavenumbers in the range of 3050-3100 cm⁻¹, an alkane C—H stretching region can be assigned to wavenumbers in the range of 2800-3000 cm⁻¹, and an alkene C═C region can be assigned to a peak centered around 905 cm⁻¹. The areas under each wavenumber range were measured and each normalized peak area was plotted versus temperature, and the resulting plot is shown in FIG. 5. The peak areas were normalized to the FTIR absorbance of an unbaked film.

As shown in FIG. 5, the peak areas associated with alkene functionality (e.g., the alkene C—H and C═C regions) diminished rapidly for bake temperatures below 100° C. while the peak areas associated with alkane functionality diminished less rapidly. This result suggests that the C═C bonds undergo reaction(s) leading to loss of alkene bonds, such as through cross-linking between ligands. Various proposals are possible to explain the loss of the alkane peak intensity below 200° C., but the data does not yet confirm a specific proposal. The solubility data strongly supports the idea of some network formation among the organic groups, although the reactions in the films may be somewhat different from solution reactions of organic compounds analogous to the current organic ligands. The film thickness and refractive index data presented in Example 5 also seem to support this hypothesis of network formation. At temperatures higher than about 210° C., a significant loss of alkane peak area can be seen which can be correlated with thermolysis of Sn—C bonds and loss of organic matter from the film.

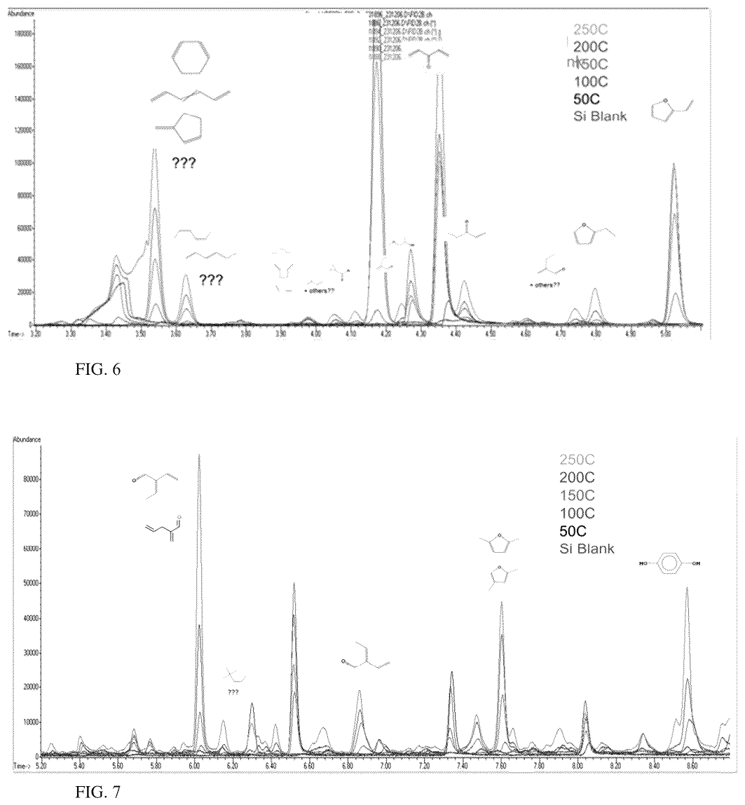

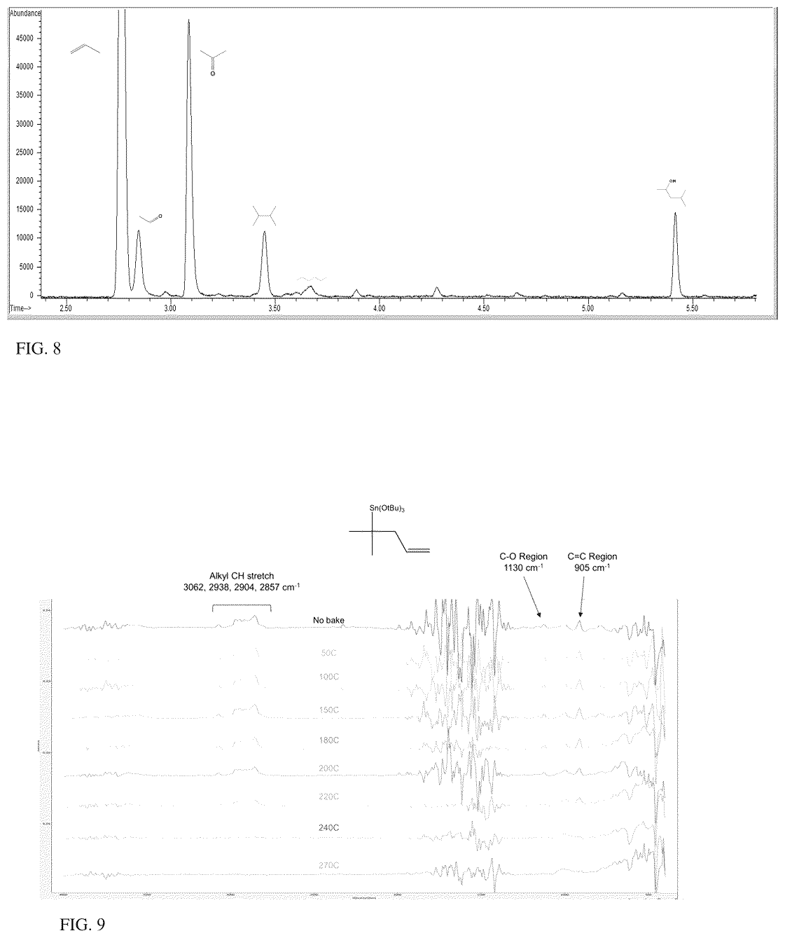

FIGS. 6 and 7 show the Gas Chromatography-Mass Spectrometry (GC-MS) as a function of bake temperature for a set of films prepared from precursor A. The baking temperature ranged from 50° C. to 250° C. The results show a variety of species outgassing from the coated wafers at various temperatures. The identified species are indicated in FIGS. 6 and 7, with some species not being fully identified to-date. FIG. 8 shows comparison GC-MS data for a set of films prepared from a precursor having an iso-propyl ligand (i-PrSn(OsBu)₃) and baked at a temperature of 200° C. Different outgassed species are identified in the GC-MS for the t-butyl ligand as compared to the GC-MS for the diene-containing ligand of precursor A.

### Precursor B

Films were prepared as described above for precursor A, except 2-methyl-4-pentenylSn(OtBu)₃ (precursor B) was used to prepare the coating solution. Each film was analyzed via FTIR and the results are shown in FIG. 9. In contrast to the results in FIG. 4, the peak areas associated with alkene functionality in the FTIR spectrum for precursor B were generally maintained until a temperature of greater than about 200° C. After about 200° C., the alkane and alkene absorbances decreased. This result suggests Sn—C cleavage and liberation of the organo group (2-methyl-4-pentenyl) as a whole without significantly polymerizing.

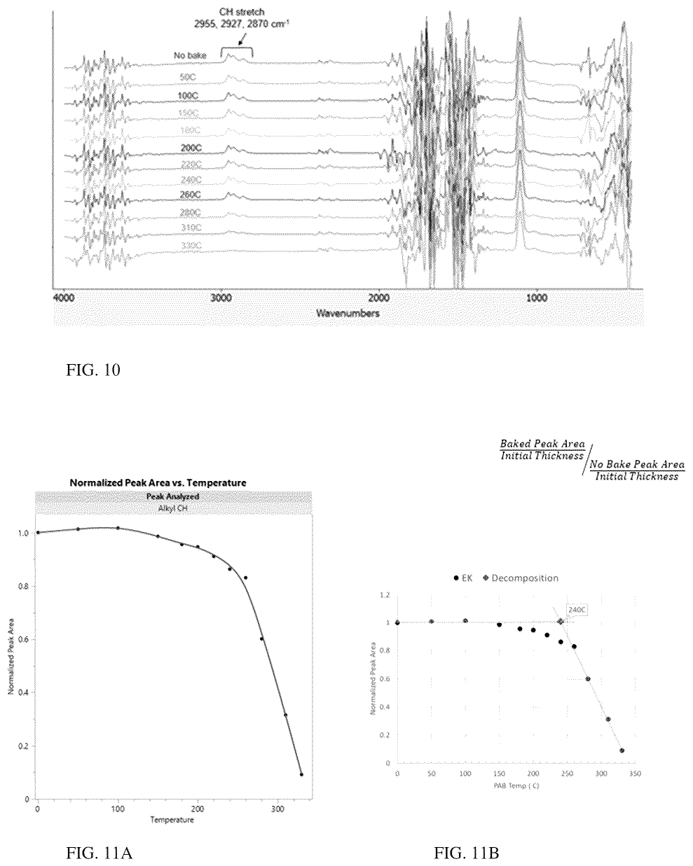

Additional films were prepared from a solution of n-butylSn(O^{t}Bu)₃. Each film was analyzed via FTIR and the results are shown in FIG. 10. The peak areas associated with alkyl C—H stretching absorption in the FTIR spectrum for this precursor were generally maintained until a temperature of greater than about 250° C., above which thermolysis is expected to cleave the C—Sn bonds. As shown in FIG. 11A, the peak areas associated with alkane functionality diminished rapidly for bake temperatures above about 250° C. As shown in FIG. 11B, the n-butyl cleavage temperature was estimated to be about 240° C., with the loss of alkane functional groups starting at around 190-200° C. These results are consistent with Sn—C cleavage of the n-butyl ligand and provide comparative data to the results discussed above for precursor A, having a diene ligand, and precursor B, having a ligand with a single C═C bond. Precursor A is believed to undergo organic polymerization and/or crosslinking reactions, which is consistent with significantly lower temperature changes in the FTIR spectra. Precursor B exhibits some smaller lower temperature changes in the FTIR spectra, which may or may not be associated with cleavage of C—Sn bonds.

This example showed how the alkane and alkene stretching regions of a diene-containing precursor changed with baking temperature, which seems to point to polymerization, crosslinking, or other chemical or physical interactions resulting from the diene ligands. This example also provided a comparison to a single C═C containing precursor which did not show evidence of polymerization, crosslinking or other interactions between the alkenyl ligands. This example also provided comparisons to precursors without unsaturated C═C bonds. The results for the non-diene-containing precursors were consistent with cleavage of the organo ligand. The results for the diene-containing ligands were surprising and suggestive of the diene participating in additional and/or more complex chemistry than the comparative precursors.

### Example 5: Resist Coatings Prepared from Various Precursors and Solubility Analysis

This example analyzes the solubility of films prepared from EBDSn(OtBu)₃ compositions and blends with other monoalkyltin compositions.

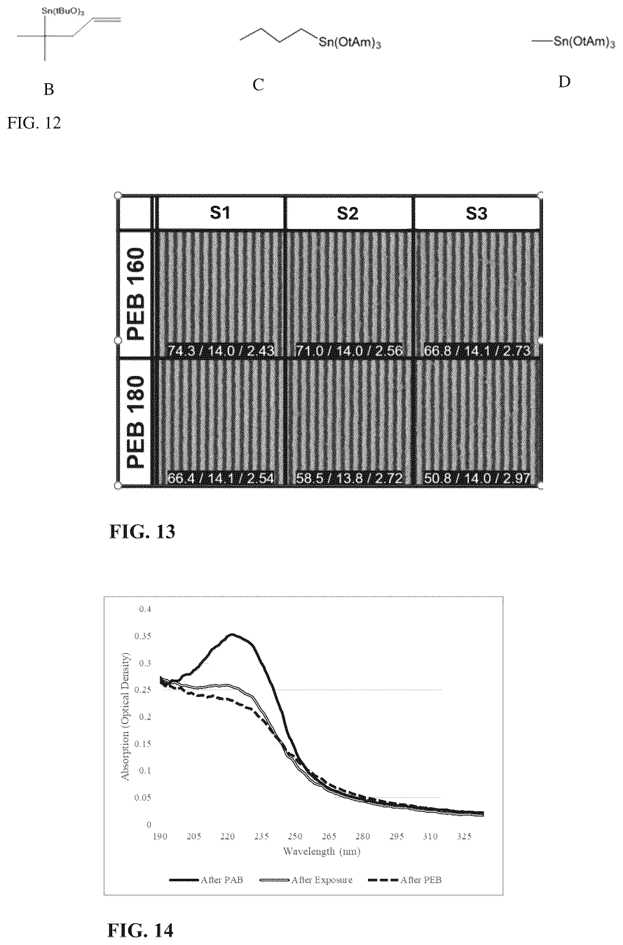

A series of precursor solutions were prepared by dissolving appropriate amounts of the EBDSn(O^{t}Bu)₃ product of Example 2 (precursor A) into PGME (A1) or 2-isopropoxyethanol (A2) to prepare resist precursor solutions having a [Sn] concentration of 0.05 M. Blended solutions of precursor A and select organotin precursors 2-methyl-4-pentenylSn(OtBu)₃ (precursor B), n-butylSn(OtAm)₃ (precursor C), and methylSn(OtAm)₃ (precursor D) were prepared by dissolving appropriate amounts of each precursor in PGME in 1:1 molar ratios to prepare blended precursor solutions AB1, AC1, and AD each having a total [Sn] concentration of 0.05M. The precursors B, C, and D used for blending were prepared by methods described in U.S. Pat. No. 10,787,466 entitled “Monoalkyl tin compounds with low polyalkyl contamination, their compositions and methods” by Edson et al. (precursor B) and the '658 application cited above (precursors C and D), both of which are incorporated by reference, and their structures are shown in FIG. 12. Table 1 below lists the precursors and precursor solution compositions used for forming films.

TABLE 1

| Sample | Type | Precursors and Compositions |
|---|---|---|
| A | Precursor | EBDSn(OtBu)₃ |
| B | Precursor | 2-methyl-4-pentenylSn(OtBu)₃ |
| C | Precursor | n-butylSn(OtAm)₃ |
| D | Precursor | methylSn(OtAm)₃ |
| A1 | Precursor Solution | 0.05M [A] in PGME |
| A2 | Precursor Solution | 0.05M [A] in 2-isopropoxyethanol |
| B1 | Precursor Solution | 0.05M [B] in 1-propanol |
| D1 | Precursor Solution | 0.05M [D] in 1-propanol |
| AB1 | Blended Precursor | 0.025M [A] + 0.025M [B] in PGME |
| | Solution | |
| AC1 | Blended Precursor | 0.025M [A] + 0.025M [C] in PGME |
| | Solution | |
| AD1 | Blended Precursor | 0.025M [A] + 0.025M [D] in PGME |
| | Solution | |

Coated wafers were prepared by spin coating precursor solutions A1, A2, B1, D1, AB1, AC1, and AD1 onto silicon wafers (area 1 in²) having 100 nm thermally grown SiO₂ (TOX) on the surface. TOX-coated Si wafers were used for these coating solubility experiments due to the readily observable thickness-driven contrast for the resulting resist films. A set of films were prepared from each precursor solution. All of the films had an initial thickness of about 25 nm. Following deposition of the films, some samples were subjected to a post apply bake (PAB) at temperatures from 100° C. to 180° C. for 120 seconds (2 minutes) and others did not receive any baking. Samples that were baked at 150° C. and 180° C. also received an initial 120 second bake at 100° C. to mimic processing conditions during a lithographic process, such as the film experiencing both a PAB and a PEB (post exposure bake). Each of the films prepared from the A1 and A2 precursor solutions were analyzed via ellipsometry using a J. A. Woollam M2000 ellipsometer. and film thicknesses and optical properties were fit to Cauchy's equation. The results are shown in Table 2 below.

TABLE 2

| | | Baking Conditions | | | |
|---|---|---|---|---|---|
| | | | | 100° C. + | 100° C. + |
| Precursor | Film | | 100° C. | 150° C. | 180° C. |
| Solution: | Measurement: | No Bake | (PAB) | (PAB) | (PAB) |
| A1 | Thickness | 25 nm | 24 nm | 21 nm | 20 nm |
| | Cauchy | 1.578 | 1.580 | 1.593 | 1.608 |
| | parameter A | | | | |
| A2 | Thickness | 20 nm | 18 nm | 16 nm | 15 nm |
| | Cauchy | 1.560 | 1.571 | 1.590 | 1.602 |
| | parameter A | | | | |

As shown in Table 2, the films prepared from precursor solutions A1 and A2 initially had a thickness of 25 nm and 20 nm, respectively. After baking, the films reduced in thickness and the Cauchy parameter A, which is generally correlated to the refractive index, increased. The decrease in film thickness and the increase in the Cauchy parameter (refractive index) correlated with increased PAB baking temperature. While not wanting to be limited by theory, the decrease in film thickness and increase in refractive index may indicate significant densification of the films upon heating.

After baking, each of the films was dipped in a solution of 2.38 wt. % tetramethylammonium hydroxide (TMAH), 5 vol. % acetic acid in PGMEA (5AA), 2-heptanone (2-hep), or water (H₂O) for 30 s to determine the solubility of the films to potential developer solvents. The solubility of each film was qualitatively assessed on an A through F scale for solubility by visual inspection of the remaining film. “A” indicates that the film was dissolved away completely, “B” indicates that the film was mostly dissolved away with little residue remaining, “C” indicates the film did not dissolve well and significant thickness remained, “D” indicates that the film was slightly visibly affected by the solution, and “F” indicates that the film was not visibly affected by the solution. The results are shown in Table 3 below.

TABLE 3

| Precursor | Developer | No | 100° C. | 100° C. + | 100° C. + |
|---|---|---|---|---|---|
| Solution | Solvent | Bake | (PAB) | 150° C. (PAB) | 180° C. (PAB) |
| A1 | TMAH | F | D | D | F |
| | 5AA | F | F | F | F |
| | 2-hep | F | F | F | F |
| | H₂O | F | F | F | F |
| A2 | TMAH | D | D | D | F |
| | 5AA | F | F | F | F |
| | 2-hep | F | F | F | F |
| | H₂O | F | F | F | F |
| B1 | 5AA | A | A | A | A |
| | 2-hep | A | A | A | A |
| D1 | 5AA | F | F | F | F |
| | TMAH | A | A | A | A |
| AB1 | 5AA | C | C | D | F |
| | 2-hep | D | D | F | F |
| AC1 | 5AA | C | D | F | F |
| | 2-hep | D | F | F | F |
| AD1 | 5AA | D | F | F | F |
| | 2-hep | D | F | F | F |

The results show that all of the films prepared with precursor solutions A1 and A2 were visibly insoluble or nearly insoluble to each of the developer solvents as deposited (without baking or irradiation). The films remained visibly insoluble or nearly insoluble to each of the developer solvents after baking, with each of the films being visibly insoluble after a 180° C. PAB. These highly insoluble films were prepared from precursor solutions of precursor A, a diene-containing composition. In contrast, all of the films prepared with precursor solution B1 were completely soluble in the tested developer solvents. These films were prepared from a precursor solution of precursor B, a precursor having an organo ligand with a single C═C bond (as shown in FIG. 12). Films prepared from a precursor solution of precursor C are known to be fully soluble in 5AA and 2-heptanone from experience, however the historical data is not shown with contemporary data in Table 3. The significantly enhanced insolubility of the films prepared with a diene-containing precursor as compared to the films prepared with a single C═C bond containing precursor are noteworthy and unexpected. The films prepared with precursor solution C1 were also completely soluble to the tested developer solvents. The films prepared with precursor solution D1 were completely soluble to TMAH but visibly insoluble to 5AA.

Blending the diene-containing composition (precursor A) with other organotin compositions (precursors B, C, or D) resulted in notable decreases in solubility as compared to the films prepared with precursor solutions B1-D1 having only precursors B, C, and D, respectively. None of the films prepared from blended precursors were fully or mostly soluble at any condition tested, and insolubility was demonstrated for solvents across different polarities. The films prepared from blends of precursor A and precursor B, C, or D showed only slightly increased solubility compared to the films prepared with the only precursor A. The enhanced insolubility of the films prepared with the blended precursor solutions AB1, AC1, and AD1 demonstrates the utility of the EBDSn(OtBu)₃ composition (precursor A) for use in modifying solubility and dose sensitivity of films prepared from blends with other organotin compositions. The results for the blended films suggest that polymerization/crosslinking of the diene ligands occurs, yet the effect is somewhat diluted by the presence of the non-diene ligands such that the (unirradiated) films are pushed closer to the solubility threshold without being fully insoluble. This is expected to be useful for negative tone patterning and further adjustment of blend ratios can be used to correspondingly adjust solubilities. Additionally, the insolubility of the films prepared with diene-containing precursors in a wide variety of solvents indicates that these films can be useful for positive tone patterning and/or as underlayers for other photoresists, such as metal oxide resists, chemically-amplified resists, and the like.

This example showed the effect of a diene-containing precursor on the solubility of films. In particular, the diene-containing precursor used independently or as part of an organotin precursor blend was shown to substantially decrease solubility of precursor coated films, even in the absence of baking. The results suggest that diene-containing precursors can be used in appropriately selected embodiments to improve both positive tone patterning and negative tone patterning.

### Example 6: Patterning Performance Improvements with Diene-Containing Precursors

This example shows the effectiveness of diene-containing ligands in precursor blends as a dissolution rate inhibitor for increasing patterning efficiency with regard to required dose with negative tone patterning.

Preparation of Organotin Precursor Solutions with Diene-Containing Ligands

In an inert environment, three organotin photoresist precursor solution samples were prepared, each having a tin concentration of 0.05 M [Sn]. A first precursor solution sample was prepared by dissolving an appropriate amount of t-BuSn(3-pentoxide)₃ (precursor E) into PGME (S1). Blended solutions of precursor E and the EBDSn(O^{t}Bu)₃ product of Example 2 (precursor A) (S2 and S3) were prepared by dissolving appropriate amounts of each precursor in an alcohol solvent blend (62% 1-pentanol/38% 1-propanol by mass), according to Table 4. Thus, precursor solution S1 was prepared without a diene-containing precursor, while precursor solutions S2 and S3 were prepared with 0.0010 and 0.00250 mol/L, respectively of diene-containing precursor A. Blended precursor solutions S2 and S3 were prepared with PGME as a solvent in contrast to precursor solution S1, which was prepared with a 1-pentanol/1-propanal mixture due to solution stability concerns. Organic solvent identity was selected to adjust solution stability for depositing a uniform film. The solvent is known to evaporate during a PAB, resulting in a substantially equivalent final composition of the formed film, irrespective of the solvent chosen.

TABLE 4

| Sample | Type | Precursors and Compositions |
|---|---|---|
| A | Precursor | EBDSn(O^{t}Bu)₃ |
| E | Precursor | t-BuSn(3-pentoxide)₃ |
| Solvent 1 | Solvent | propylene glycol methyl ether (PGME) |
| Solvent 2 | Solvent | 62% 1-pentanol, 38% 1-propanol by mass |
| S1 | Precursor | 0.050M [E] in Solvent 2 |
| | Solution | |
| S2 | Precursor | 0.0490M [E] and 0.0010M [A] in Solvent 1 |
| | Solution | |
| S3 | Precursor | 0.0475M [E] and 0.0025M [A] in Solvent 1 |
| | Solution | |

Deposition and Lithographical Patterning with Organotin Precursor Solutions

The precursor solutions were deposited via spin coating onto 300 mm diameter Si wafers with spin-on-glass underlayer to produce films with thicknesses from about 24 to about 26 nm, confirmed using ellipsometry. The coated wafers were subjected to a 60 second, 100° C. post application bake (PAB). Then line-space patterns having a target critical dimension (CD) of 14 nm on a 28 nm pitch (14p28) were produced for each sample by exposing the samples to 13.5 nm EUV radiation between about 40 mJ/cm² to about 100 mJ/cm² using an ASML NXE3400B exposure tool to create an array of patterns within fields on the wafer, wherein each field corresponds to the mask pattern printed at a specific dose. As is customary in the art, this type of exposure is referred to as a dose meander exposure. By exposing the same 14p28 pattern at different doses across each photoresist film sample, the dose required for printing the desired 14p28 pattern for a given photoresist film sample (i.e., the dose-to-size for printing 14 nm lines on a 28 nm pitch) can be determined through inspection of each field after processing is complete. Following EUV exposure, the wafers were then split in half, whereupon half of each wafer was subjected to a 60 second, 160° C. post exposure bake (PEB) and the other half to a 60 second, 180° C. PEB. A solution of propylene glycol methyl ether acetate (PGMEA) containing 5% acetic acid by volume (5AA) was then used to develop the wafers in a negative tone development process prior to a 60 second, 250° C. hard bake.

After the hard bake, the film samples were inspected using a Hitachi CD-SEM to determine the dose required to image the 14p28 pattern. The dose required to image the target 14p28 line-space pattern can be referred to as dose-to-size (DtS). The lithographical performance data described herein is presented in Table 5 and the CD-SEM images are shown in FIG. 13.

TABLE 5

| Photoresist | PEB | | Characteristic |
|---|---|---|---|
| Precursor | Temperature | DtS | Dimension (CD) |
| Solution Sample | (° C.) | (mJ/cm²) | (nm) |
| S1 | 160 | 74.3 | 14.0 |
| | 180 | 66.4 | 14.1 |
| S2 | 160 | 71.0 | 14.0 |
| | 180 | 58.5 | 13.8 |
| S3 | 160 | 66.8 | 14.1 |
| | 180 | 50.8 | 14.0 |

As shown in Table 5, the addition of diene-containing precursor A inversely correlated to the radiation dose needed to produce 14 nm line-space patterns at a given PEB temperature. For example, with a PEB bake temperature of 180° C., 66.4 mJ/cm² were required to achieve approximately 14 nm line-space patterns when no diene-containing ligands were present, a value that was reduced to 58.5 mJ/cm² and 50.8 mJ/cm² with the incorporation of 2% and 5% diene-containing precursor material by mole, respectively. Thus, the presence and the concentration of the diene-containing precursor in the precursor solution was correlated with a decrease in DtS. However, as shown in FIG. 13, there is also a correlation between the line width roughness and the presence/concentration of the diene-containing precursor. For example, with a PEB of 180° C., developed patterned films prepared from S1, S2, and S3 showed an average line width roughness (LWR) of 2.54 nm, 2.72 nm, and 2.97 nm, respectively. This correlation was also seen for the samples subjected to the lower PEB temperature. For each sample, the DtS was lower when processed with a higher PEB temperature, yet the LWR was higher. While not wanting to be limited by theory, it is believed that the presence of a diene-containing ligand within the precursor composition enables a polymerization/crosslinking reaction to occur between these ligands, resulting in a film having a polymeric/crosslinked network of C—C bonds that bridge between Sn centers, which is consistent with the solubility results presented in Example 5. The results suggest that the crosslinking mechanism may function to increase the average molecular weight of the organic species in the film connecting the tin atoms and to decrease the threshold for insolubility of the resist film. The lower solubility threshold necessitates a lower dose of radiation to achieve an extent of dealkylation sufficient to render the irradiated material insoluble in the developer solution.

This example demonstrates that by including a diene-containing precursor in an organotin photoresist composition, a desired characteristic dimension (CD) can be achieved with a lower dose. The use of diene-containing ligands can act as a dissolution rate inhibitor to increase patterning efficiency across varying processing conditions. These effects are observed with surprisingly low amounts of the diene ligands in a precursor blend. Specifically, even at 2 mol % or 5 mol %, the diene ligands have significant effects on the film properties.

### Example 7: Surface Wettability Improvements with Diene-Containing Precursors

This example compares the water contact angles for organotin photoresist films prepared with and without diene-containing ligands.

In an inert environment, two organotin photoresist precursor solution samples were prepared, each having a tin concentration of 0.05 M [Sn]. The first precursor solution sample (S4) was prepared by dissolving an appropriate amount of methylfuranyl Sn(O^{t}Bu)₃ (precursor F, see structure above) into 4-methyl-2-pentanol (4M2P). The second precursor solution sample (S5) was prepared by dissolving an appropriate amount of methyl tin tris(tert-pentoxide) (precursor G) and t-BuSn(3-pentoxide)₃ (precursor E) in an alcohol solvent blend (62% 1-pentanol/38% 1-propanol by mass) at tin concentrations of 0.01 and 0.04 mol/L, respectively, according to Table 6. Precursor F has a diene-containing ligand; precursors E and G do not have diene-containing ligands.

TABLE 6

| Sample | Type | Precursors and Compositions |
|---|---|---|
| E | Precursor | t-BuSn(3-pentoxide)₃ |
| F | Precursor | methylfuranyl Sn(O^{t}Bu)₃ |
| G | Precursor | methyl tin tris(tert-pentoxide) |
| Solvent 1 | Solvent | 4M2P |
| Solvent 2 | Solvent | 62% 1-pentanol, 38% 1-propanol |
| | | by mass |
| S4 | Precursor Solution | 0.050M [F] in Solvent 1 |
| S5 | Precursor Solution | 0.01M [G] and 0.04M [E] in |
| | | Solvent 2 |

The precursor solutions were then deposited onto 300 mm diameter silicon wafers with a spin-on-glass underlayer via spin coating at 1500 rpm for 45 seconds. One wafer coated with precursor solution S4 and one wafer coated with precursor solution S5 were reserved and not subjected to a baking process. The remaining coated wafers were subjected to a 2-minute post-application bake (PAB) at 100° C., 150° C., or 180° C. Ellipsometry was performed to determine the contact angle between the organotin coating and a water droplet. Measured contact angles for each wafer sample are displayed in Table 7.

TABLE 7

| Precursor | Post Application Bake | |
|---|---|---|
| Solution | (PAB) Temperature (° C.) | Contact Angle (°) |
| S4 | No Bake (NB) | 49.40 ± 0.20 |
| | 100° C. | 43.70 ± 0.50 |
| | 150° C. | 39.43 ± 0.88 |
| | 180° C. | 44.64 ± 1.08 |
| S5 | No Bake (NB) | 71.59 ± 4.16 |
| | 100° C. | 71.88 ± 1.18 |
| | 150° C. | 71.59 ± 1.29 |
| | 180° C. | 74.23 ± 0.88 |

Table 7 shows that the films formed from precursor solution S4, having a diene-containing precursor, had lower contact angles than equivalently processed films formed from precursor solution S5, having no diene-containing precursors. The decrease in contact angles was from about 22 to 32 degrees. The smallest decrease in contact angle was for the non-baked samples. The results indicate that the films formed from the diene-containing precursor solution were more hydrophilic at each processing temperature. Consistent with this view, the as deposited films were found to be insoluble, while films made with corresponding ligands with the furan ring replaced by tertahydrofuran were found to be soluble as described in published U.S. Patent Application No. 2023/0374338 to Jilek et al., entitled “Radiation sensitive organotin compositions having oxygen heteroatoms in hydrocarbyl ligand”, incorporated herein by reference. This result is consistent with a polymerization/crosslinking reaction occurring between the diene ligands. Considering the films formed from precursor solution S4, the least hydrophilic film was the non-baked sample. This result further suggests that polymerization of the diene ligands can occur during a PAB process in which the film is heated after deposition.

This example demonstrated the increase in hydrophilicity associated with organotin resist films prepared with diene-containing ligands. The increase in hydrophilicity is expected to improve the wettability and surface interaction with a developer solvent and lead to better cross-wafer uniformity during the development process, in particular during positive tone development with aqueous solvents.

### Example 8: UV-Visibility Study of Photoresists Prepared from Diene-Containing Precursors

This example shows the effects of radiation exposure, polymerization inhibitors, and heating on the UV absorption of various photoresist films prepared from a diene-containing precursor solution.

Preparation of Organotin Precursor Solutions with Radical Polymerization Inhibitors

In an inert environment, a stock solution of an organotin photoresist precursor solution was prepared by dissolving an appropriate amount of the EBDSn(O^{t}Bu)₃ product of Example 2 (precursor A) into PGME to prepare a solution having a [Sn] concentration of 0.05M. An aliquot of the stock solution was reserved as precursor solution sample S6. The remaining stock solution was divided into two aliquots. A selected radical polymerization inhibitor was added to each of the two aliquots at a selected concentration to form precursor solution samples S7 and S8, as shown in Table 8.

TABLE 8

| Photoresist | | | |
|---|---|---|---|
| Precursor | | | Polymerization |
| Solution | Organotin | Polymerization | Inhibitor |
| Sample | Precursor | Inhibitor | Concentration |
| S6 | EBDSn(Ot-Bu)₃ | None | N/A |
| S7 | EBDSn(Ot-Bu)₃ | 4-hydroxy-TEMPO | 0.005M |
| S8 | EBDSn(Ot-Bu)₃ | Butylated | 0.002M |
| | | hydroxytoluene | |
| | | (BHT) | |

### Film Deposition and UV-Visible Spectroscopy Characterization of the Films

The prepared precursor solution samples were deposited onto quartz slides via spin coating for 45 seconds at 1500 rpm and subjected to a 2 minute, 30° C. post application bake. In total, 9 slides (3 slides prepared from each of S6, S7, and S8) were coated to measure the spectral properties of the three film compositions at three different exposure doses. A UV-Visibility spectrophotometer was used to generate a full absorption spectrum for both the top and bottom of each of the 9 slides at three distinct stages of processing. The geometric mean of the wavelength-corresponding absorption values for the top and bottom of each slide was then calculated to generate a final spectrum for characterizing each film. Such a spectrum was generated after the post application bake, after exposure to one of the three radiation doses, and after a 30 second, 100° C. post exposure bake (PEB), with about 45 minutes elapsing between processing stages.

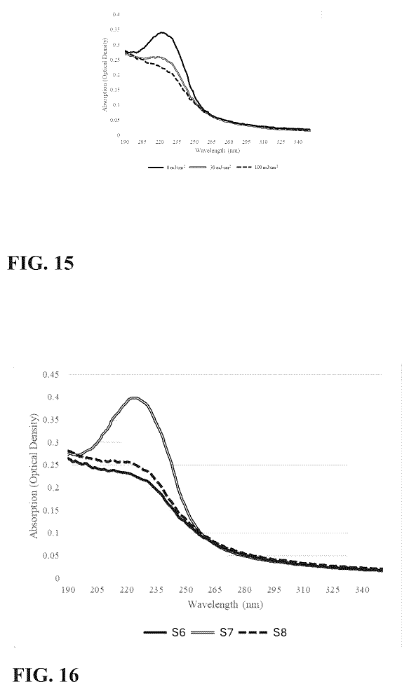

FIGS. 14-16 show the UV-visibility spectroscopy data that was collected. The UV-Visible Spectroscopy absorption wavelength range associated with the presence of a thermodynamically stable organotin dodecamer is known to be about 210 to about 245 nm. FIG. 14 shows the UV-Visible spectra generated throughout all three processing stages of a photoresist film sample prepared from precursor solution S6: after the PAB, after a subsequent exposure to a 30 mJ/cm² EUV radiation dose, and after the subsequent PEB. FIG. 14 shows a peak in the organotin dodecamer region that is most prevalent after the PAB (and before exposure), that has significantly degraded after radiation exposure, and that has further degraded after the PEB. The data suggests that dodecameric structures are formed in films prepared from diene-containing organotin precursor solutions. The data also suggests that the dodecameric structures degrade during both radiation exposure and post exposure bake (PEB). FIG. 15 shows spectral data for three slides of photoresist film samples prepared from precursor solution S6 which were subjected to 254 nm UV radiation doses of 0 mJ/cm², 30 mJ/cm², and 100 mJ/cm², respectively. The film that was not subjected to radiation exposure (0 mJ/cm²) showed the most prevalent peak in the organotin dodecamer region. The film that was subjected to the highest radiation dose (100 mJ/cm²) showed the smallest peak in the organotin dodecamer region. The results suggest that the degradation of dodecamer structures in photoresist films prepared from diene-containing precursor solutions increases with increasing radiation dose.

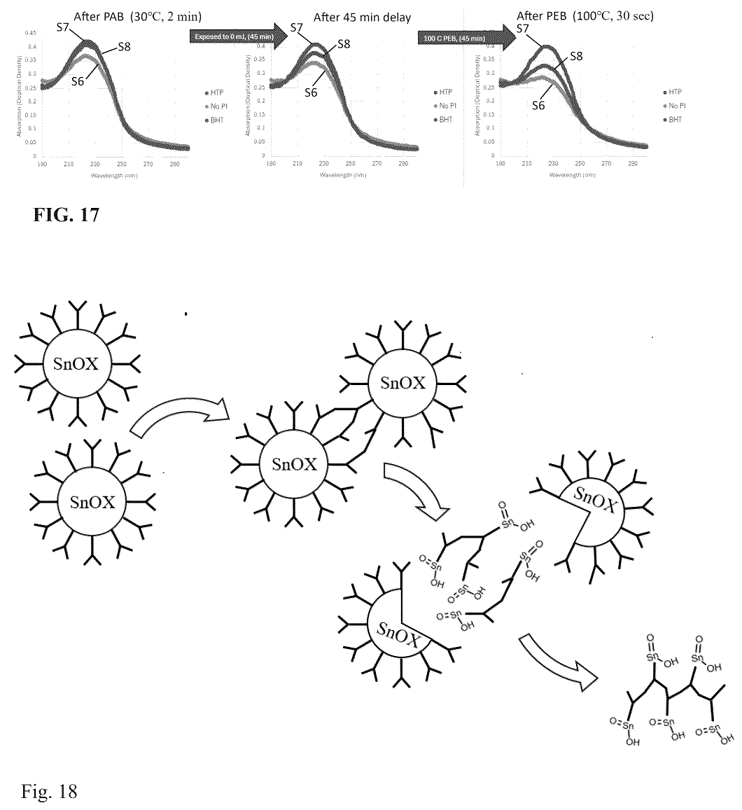

FIG. 16 shows the UV-visible spectra generated by photoresist film samples prepared from S6, S7, and S8 after exposure to a 30 mJ/cm² radiation dose and a 100° C. PEB. The most prominent peak in the organotin dodecamer region is from the sample prepared from S7, which includes the polymerization inhibitor 4-hydroxy-TEMPO. The least prominent peak in the organotin dodecamer region is from the sample prepared from S6, which is absent a polymerization inhibitor. The spectra from the sample prepared from S8, which includes the polymerization inhibitor BHT, showed an intermediate peak in the dodecamer region. FIG. 17 shows UV-visible spectra generated for samples with no polymerization inhibitor S6, 4-hydrox-Tempo (HTP) S7 or BHT S8 after PAB of 30° C. for two minutes, after a further 45 minutes delay and then after a PEB of 100° C. for 30 seconds. The results again demonstrate that the samples without a polymerization inhibitor have absorption spectra indicating the loss of a cluster structure. A comparison of the three spectra suggests that the addition of known radical polymerization inhibitors BHT and 4-hydroxy-TEMPO modulated the polymerization of the diene ligands and the degradation of dodecamer structures through the end of the three processing stages. This suggests that chemical changes and resulting solubility contrast from radiation exposure and baking of films prepared with diene-containing precursors may proceed through a radical polymerization mechanism. The data also shows that different additive compounds can inhibit the polymerization and concurrent degradation of dodecamer structures with varying effectiveness. This suggests that an additive can be selected and added at a determined concentration to precisely control the extent of polymerization and modulate the solubility contrast throughout processing.

This example demonstrated that radical polymerization inhibitors can provide effective control of polymerization of diene-containing ligands in organotin photoresist films, which can be beneficial for solubility tuning in development processes.

### Example 9: Solubility Study of Photoresists Prepared from Diene-Containing Precursors

This example shows the effectiveness of radical polymerization inhibitors in moderating polymerization in photoresist films prepared from diene-containing precursors and in enabling tuning of photoresist film solubilities to increase patterning efficiency.

Preparation of Organotin Precursor Solutions with Radical Polymerization Inhibitors

In an inert environment, a stock solution of an organotin photoresist precursor solution was prepared by dissolving an appropriate amount of the EBDSn(O^{t}Bu)₃ product of Example 2 (precursor A) into PGME to prepare a solution having a [Sn] concentration of 0.05M. An aliquot of the stock solution was reserved as precursor solution sample S9. The remaining stock solution was divided into five aliquots. A selected radical polymerization inhibitor was added to each of the five aliquots at a selected concentration to form precursor solution samples S10 to S14, as shown in Table 9.

TABLE 9

| Photoresist | | | |
|---|---|---|---|
| Precursor | | | Polymerization |
| Solution | Organotin | Polymerization | Inhibitor |
| Sample | Precursor | Inhibitor | Concentration |
| S9 | EBDSn(Ot-Bu)₃ | None | N/A |
| S10 | EBDSn(Ot-Bu)₃ | Mequinol | 0.005M |
| S11 | EBDSn(Ot-Bu)₃ | Butylated | 0.005M |
| | | hydroxytoluene (BHT) | |
| S12 | EBDSn(Ot-Bu)₃ | 4-tertbutylcatechol | 0.005M |
| S13 | EBDSn(Ot-Bu)₃ | 4-Hydroxy-TEMPO | 0.002M |
| S14 | EBDSn(Ot-Bu)₃ | Butylated | 0.002M |
| | | hydroxytoluene (BHT) | |

### Film Deposition and Solubility Analysis of the Films

Each of the prepared precursor solution samples were deposited onto a set of 4 silicon wafers with a thermally oxidized SiO₂ layer, for a total of 24 silicon wafers. Deposition was achieved through spin coating for 45 seconds at 1500 rpm to form a thin film. Each set of four coated wafers were then subjected to either no post application bake (“No Bake”) or a 2-minute PAB at a temperature of 30° C., 100° C., 150° C., or 180° C. Subsequently, each coated wafer was dipped in a developer solution of 5% acetic acid by volume in PGMEA (5AA) to test the processed film's solubility in the solution. Characterization of the solubility was done qualitatively by visual inspection. The results are shown in Table 10. “Y” indicates that the film was fully dissolved. “N1” indicates that a faint residue remained. “N5” indicates that the film was not visibly affected by the developer solution. N2, N3, and N4 are intermediate classifications within the range of N1 to N5. Data that was not collected is indicated by a dashed line.

TABLE 10
Precursor

| Solution | PAB condition | | | | |
|---|---|---|---|---|---|
| Sample | No Bake | 30° C. | 100° C. | 150° C. | 180° C. |
| S9 | — | N5 | N5 | N5 | N5 |
| S10 | — | Y | N1 | N5 | N5 |
| S11 | — | N1 | N5 | N5 | N5 |
| S12 | — | Y | Y | Y | N5 |
| S13 | Y | — | N3 | N5 | N5 |
| S14 | Y | — | N5 | N5 | N5 |

As shown in Table 10, the films prepared with precursor solution S9, having no radical polymerization inhibitor added, showed no dissolution of the deposited films after contact with the 5AA solvent. The result was the same for each of the PAB temperatures used. The lack of solubility of the films formed from diene-containing precursor solution S9 is consistent with a polymerization/crosslinking reaction occurring between the diene-ligands even in the absence of radiation exposure. The films prepared from precursor solution S10, having 0.005M of mequinol as a radical polymerization inhibitor, showed full dissolution after a 30° C. PAB, reduced solubility after a 100° C. PAB, and no solubility after a 150° C. or a 180° C. This temperature-dependent progression suggests that polymerization of the diene-ligands is temperature driven, yet modulated by the presence of the mequinol. The temperature-dependent progression toward insolubility is also seen in the film samples prepared with precursor solution samples S11-S14, with the “No Bake” films from S13 and S14 representing films exposed to no more than room temperature. The effect of different radical polymerization inhibitors can be seen by comparing the results from films prepared with precursor solutions S10-S12. These precursor solutions have different radical polymerization inhibitors (mequinol, BHT, and 4-tertbutylcatechol, respectively) but the same 0.005M inhibitor concentration. The results show that 4-tertbutylcatechol was the most effective at maintaining solubility of the film. Solubility was maintained even after a 150° C. PAB. This suggests that 4-tertbutylcatechol is highly effective as an additive for modulating polymerization of the organotin diene-ligands. The effect of different radical polymerization inhibitors can also be seen by comparing the results from films prepared with precursor solutions S13 and S14. These precursor solutions have different radical polymerization inhibitors (4-hydroxy-TEMPO and BHT, respectively) but the same 0.002M inhibitor concentration. The results show that 4-hydroxy-TEMPO was somewhat more effective at maintaining solubility of the film after a 100° C. PAB than BHT. Furthermore, the effect of different concentration of the same radical polymerization inhibitor can be seen by comparing the results from films prepared with precursor solutions S12 and S14. These precursor solutions have 0.005 M and 0.002 M of BHT, respectively). Full solubility was maintained with the films formed with the higher concentration of BHT even after a 150° C. PAB, while the films formed with the lower concentration of BHT were shown to be fully insoluble after a 100° C. PAB. This suggests that control of the concentration of a radical polymerization inhibitor can be effective for modulating polymerization of organotin diene-ligands.

This study demonstrated that the addition of known radical polymerization inhibitors to a precursor solution can effectively increase the resulting film's solubility in a PGMEA-based developer solution and decrease thermally-induced solubility changes. The results further suggest that the evidenced solubility changes for films prepared from diene-containing precursor solutions are at least in part the result of a radical polymerization mechanism. This study also demonstrated that the type and concentration of a radical polymerization inhibitor may be selected to optimize film solubility at varying process conditions. Thus, the use of radical polymerization inhibitors can be used to effectively tune and control film solubility over a range of process conditions and accordingly leverage the advantages of organotin photoresist films prepared with diene-containing precursors while reducing the variability in patterning performance.

### Further Inventive Concepts

A1. A method for synthesizing a (polyene-containing) monoorgano tin trialkoxide, the method comprising:
reacting MSn(OR′)₃ with RY to form RSn(OR′)₃, wherein M is an alkali metal, Y is an organosulfonate group, R is an organo group with 1 to 31 carbon atoms and forming a C—Sn bond in the product RSn(OR′)₃; and R′ is an organo group with 1 to 10 carbon atoms.

A2. The method of inventive concept A1 wherein R comprises at least two acyclic and/or aliphatic C═C bonds.

A3. The method of inventive concept A1 wherein R comprises a conjugated diene.

A4. The method of inventive concept A1 wherein R and/or R′ comprise heteroatoms.

A5. The method of inventive concept A1 wherein R comprises I, F, O or S atoms.

A6. The method of inventive concept A1 wherein R comprises one or more fluorine atoms.

A7. The method of inventive concept A1 wherein R comprises an aromatic group.

A8. The method of inventive concept A1 wherein R comprises a —CF₃ group.

A9. The method of inventive concept A1 wherein R comprises a methyl furan group or a methyl thiophene group.

A10. The method of inventive concept A1 wherein R comprises a 2-ethyl-1,3-butadiene group, or a 2-methy-1,3-butadiene group.

A11. The method of inventive concept A1 wherein R′ is a methyl, an ethyl, a propyl, an i-propyl, a t-butyl, an i-butyl, silyl, sec-butyl, pentan-3-yl, or a t-amyl group.

A12. The method of inventive concept A1 wherein M is K.

A13. The method of inventive concept A1 wherein Y is tosylate.

A14. The method of inventive concept A1 wherein reacting is performed at a temperature from about 35° C. to about 120° C.

A15. The method of inventive concept A1 wherein RSn(OR′)₃ is 3-methylene-pent-4-en-yltin tris(tert-butyl oxide).

A16. The method of inventive concept A1 wherein RSn(OR′)₃ is (furan-3-yl) methyl tin tris(tert-butyl oxide) or (thiophen-3-yl) methyl tin tris(tert-butyl oxide).

B1. A radiation sensitive film comprising a network with Sn (IV) atoms, oxo ligands and hydroxo ligands, and with polymerized/crosslinked polyene ligands with a plurality of C—Sn bonds.

B2. The radiation sensitive film of inventive concept B1 wherein the C—Sn bonds are radiation sensitive.

B3. The radiation sensitive film of inventive concept B1 wherein the network is a reaction product of an organometallic precursor compound represented by the formula RSnL₃, wherein R is an organo group with 1 to 31 carbon atoms and at least two conjugated C═C bonds and forms a C—Sn bond, and each L is independently a hydrolysable ligand.

B4. The radiation sensitive film of inventive concept B3 wherein the reaction product comprises a hydrolysis product and/or a polymerized/crosslinked product.

B5. The radiation sensitive film of inventive concept B1 wherein the film comprises Sn—O—Sn and Sn—OH bonds.

B6. The radiation sensitive film of inventive concept B1 wherein the film comprises an oxo-hydroxo network comprising Sn—O—Sn, Sn—OH bonds, and Sn—R^{c}—R^{c}—Sn bonds, wherein R^{c} represents crosslinked R groups.

B7. The radiation sensitive film of inventive concept B1 wherein the radiation sensitive film is insoluble in organic solvents.

B8. The radiation sensitive film of inventive concept B1 formed by depositing an organometallic precursor compound represented by the formula RSnL₃, wherein R is an organo group with 1 to 31 carbon atoms and at least two conjugated C═C bonds and forms a C—Sn bond, and each L is independently a hydrolysable ligand under hydrolyzing conditions onto a substrate.

B9. The radiation sensitive film of inventive concept B1 wherein the radiation sensitive film further comprises a radical scavenging compound.

B10. The radiation sensitive film of inventive concept B1 formed by depositing a combination of organometallic precursor compounds represented by RSnL₃, and R^{a}SnL′₃, wherein R is an organo group with 1 to 31 carbon atoms and at least two conjugated C═C bonds and forms a C—Sn bond, R^{a} is an organo group with 1 to 31 carbon atoms and forming a C—Sn bond and free of conjugated polyene functionality, and each L and L′ is independently a hydrolysable ligand.

B11. A structure comprising a substrate with a surface and the radiation sensitive film of any one of inventive concepts B1-B10 on the surface of the substrate.

B12. The structure of inventive concept B11 wherein the substrate comprises a silicon wafer.

C1. A method of patterning a radiation sensitive film, the method comprising:
forming a radiation sensitive organometallic film on a substrate surface comprising depositing onto the surface a solution comprising an organic solvent, two or more organometallic compounds represented by the formula RSnL₃, where each R is an organo group with 1 to 31 carbon atoms, and forms a C—Sn bond, each L is independently a hydrolysable group, and at least one organometallic compound comprises at least two conjugated C═C bonds; and irradiating the radiation sensitive organometallic film, following hydrolysis of hydrolysable ligands to form an oxo-hydroxo network, with patterned radiation to form a virtual image having irradiated regions and non-irradiated regions.

C2. The method of inventive concept C1 wherein each L is independently OR′, wherein R′ is an organo group with 1 to 10 carbon atoms.

C3. The method of inventive concept C1 wherein R comprises an aromatic group.

C4. The method of inventive concept C1 wherein R and/or R′ comprise heteroatoms.

C5. The method of inventive concept C1 wherein the solution comprises a blend of a first organometallic compound represented by the formula RSnL₃ and a second organometallic composition represented by the formula R^{a}SnL′₃, wherein L and L′ each independently a hydrolysable ligand, R is an organo group having at least two conjugated C═C bonds and forms a C—Sn bond, R^{a} is an organo group with 1 to 31 carbon atoms and forms a C—Sn bond, and wherein the R and R^{a} can optionally comprise heteroatoms.

C6. The method of inventive concept C5 wherein the non-irradiated regions are soluble in an organic solvent.

C7. The method of inventive concept C6 wherein the organic solvent comprises PGMEA.

C8. The method of inventive concept C1 wherein the patterned radiation comprises a pattern of EUV radiation.

C9. The method of inventive concept C9 wherein the EUV radiation has a dose from about 1 mJ/cm² to about 100 mJ/cm².

C10. The method of inventive concept C1 wherein the radiation sensitive film further comprises a polymerization inhibitor.

C11. The method of inventive concept C1 comprising hydrolyzing the hydrolysable ligands to the tin with in situ water vapor.

C12. The method of inventive concept C1 further comprising, prior to the irradiating step, performing a post application bake at a temperature from about 25° C. to about 200° C. for about 10 seconds to about 10 minutes.

C13. The method of inventive concept C1 further comprising, after the irradiating step, performing a post exposure bake at a temperature from about 45° C. to about 250° C. for about 0.1 minute to about 10 minutes.

C14. The method of inventive concept C1 further comprising, after the irradiating step, developing to substantially remove the non-irradiated regions of the virtual image to form a negative tone pattern, or to substantially remove the irradiated portion of the virtual image to form a positive tone pattern.

C15. The method of inventive concept C15 wherein the developing comprises dry development.

C16. The method of inventive concept 15 wherein the developing comprises contacting with a developer liquid.

D1. A method of patterning a radiation sensitive film, the method comprising:
forming a radiation sensitive organometallic film on a substrate surface comprising depositing onto the surface a solution comprising an organic solvent, a polymerization inhibitor, and an organometallic compound represented by the formula RSnL₃, where R is an organo group with 1 to 31 carbon atoms and at least two conjugated C═C bonds and forms a C—Sn bond, each L is independently a hydrolysable group; and
irradiating the radiation sensitive organometallic film, following hydrolysis of hydrolysable ligands to form an oxo-hydroxo network, with patterned radiation to form a virtual image having irradiated regions and non-irradiated regions.

D2. The method of inventive concept D1 wherein each L is independently OR′, wherein R′ is an organo group with 1 to 10 carbon atoms.

D3. The method of inventive concept D1 wherein R comprises a diene.

D4. The method of inventive concept D1 wherein R and/or R′ comprise heteroatoms.

D5. The method of inventive concept D1 wherein the non-irradiated regions are soluble in an organic solvent.

D6. The method of inventive concept D5 wherein the organic solvent comprises PGMEA.

D7. The method of inventive concept D1 wherein the patterned radiation comprises a pattern of EUV radiation.

D8. The method of inventive concept D7 wherein the EUV radiation has a dose from about 1 mJ/cm² to about 100 mJ/cm².

D9. The method of inventive concept D1 wherein the solution comprises a second organometallic compounds represented by the formula R^{a}SnL′₃, wherein R^{a} is an organo group with 1 to 31 carbon atoms and forming a C—Sn bond and free of conjugated polyene functionality and each L′ is independently a hydrolysable group that is the same or different form L

D10. The method of inventive concept D1 comprising hydrolyzing the hydrolysable ligands to the tin with in situ water vapor.

D11. The method of inventive concept D1 further comprising, prior to the irradiating step, performing a post application bake at a temperature from about 25° C. to about 200° C. for about 10 seconds to about 10 minutes.

D12. The method of inventive concept D1 further comprising, after the irradiating step, performing a post exposure bake at a temperature from about 45° C. to about 250° C. for about 0.1 minute to about 10 minutes.

D13. The method of inventive concept D1 further comprising, after the irradiating step, developing to substantially remove the non-irradiated regions of the virtual image to form a negative tone pattern, or to substantially remove the irradiated portion of the virtual image to form a positive tone pattern.

D14. The method of inventive concept D13 wherein the developing comprises dry development.

D15. The method of inventive concept D14 wherein the developing comprises contacting with a developer liquid.

Z. A solution comprising an organic solvent and the organometallic compound of any one of claims 1-18.

Z1. The solution of inventive concept Z wherein the organic solvent comprises an alcohol, an aromatic hydrocarbon, an aliphatic hydrocarbon, an ester, an ether, a ketone, or combinations thereof.

Z2. The solution of inventive concept Z wherein the solution has a concentration of the organometallic compound from about 0.00025M to about 1.4M based on tin concentration.

Z3. The solution of inventive concept Z wherein the organic solvent comprises a primary alcohol or PGME.

Z4. The solution of inventive concept Z wherein the organic solvent comprises 1-propanol, 1-pentanol, 4-methyl-2-pentanol, 2-isopropoxyethanol, or combinations thereof.

Z5. The solution of inventive concept Z wherein the organic solvent comprises an aromatic solvent.

Z6. The solution of inventive concept Z having a controlled amount of water.

Z7. The solution of inventive concept Z having from about 200 ppm to about 10,000 ppm by weight of water.

Z8. The solution of inventive concept Z further comprising a polymerization inhibitor compound.

Z9. The solution of inventive concept Z8 wherein the polymerization inhibitor compound is a radical scavenger compound comprising TEMPO, 4-hydroxy-TEMPO, mequinol, butylated hydroxytoluene (BHT), or 4-tertbutylcatechol, or a combination thereof.

Z10. The solution of inventive concept Z8 wherein the solution has a concentration of the radical scavenger compound from about 0.00005M to about 0.25M.

Z11. The solution of inventive concept Z further comprising a second organometallic composition represented by the formula R^{a}SnL′₃ and distinct from the organometallic compound, wherein L is a hydrolysable ligand and R^{a} is an organo group with 1 to 31 carbon atoms and forming a C—Sn bond.

Z12. The solution of inventive concept Z11 wherein the solution has a concentration of R^{a}Sn moieties from about 0.0025M to about 1.4M based on tin concentration.

Z13. The solution of inventive concept Z12 wherein the molar ratio of RSn to R^{a}Sn is from about 0.25% to about 25%.

Z14. The solution of inventive concept Z11 wherein each L′ is independently an alkoxide, a dialkylamide, an alkylacetylide, an alkylsilylamide, or a combination thereof.

Z15. The solution of inventive concept Z11 wherein R^{a} comprises —CH₃, a saturated organo group, or an organo group having one C═C bond, an aromatic group, or a combination thereof.

Z16. The solution of inventive concept Z11 wherein the second organometallic composition comprises methylSn(OtAm)₃, n-butylSn(OtAm)₃, or 2-methyl-4-pentenylSn(O^{t}Bu)₃, or a combination thereof.

Z17. A method for forming a radiation patternable coating comprising:
depositing the solution of any one of claims Z-Z16 onto a substrate to form a radiation sensitive organometallic film.

Z18. The method of inventive concept Z17 wherein the radiation sensitive organometallic film is insoluble in TMAH, PGMEA, 5 vol. % acetic acid in PGMEA, 2-heptanone, or water.

Z19. The method of inventive concept Z17 further comprising heating the radiation sensitive organometallic film to form a radiation sensitive organometallic film having bridging ligands spanning between at least two tin atoms and forming C—Sn bonds to each Sn atom.

Z20. A method for forming a radiation patternable coating comprising:
depositing the solution of inventive concept Z8 onto a substrate to form a radiation sensitive organometallic film to form a film comprising a radical scavenging compound.

Y. A structure comprising a radiation sensitive organometallic film and a substrate supporting the radiation patternable film on a surface, wherein the film comprises the organometallic compound of claim 1 and/or a reaction product of the organometallic compound of any one of claim 1-18.

Y1. The structure of inventive concept Y wherein the reaction product comprises a hydrolysis product and/or a polymerized/crosslinked product.

Y2. The structure of inventive concept Y wherein the film comprises radiation sensitive Sn—C bonds.

Y3. The structure of inventive concept Y2 wherein the film comprises Sn—O—Sn and Sn—OH bonds.

Y4. The structure of inventive concept Y wherein the film comprises an oxo-hydroxo network comprising Sn—O—Sn, Sn—OH bonds, and Sn—R^{c}—R^{c}—Sn bonds, wherein R^{c} represents crosslinked R groups.

Y5. The structure of inventive concept Y wherein the radiation sensitive organometallic film is insoluble in organic solvents.

Y6. The structure of inventive concept Y wherein the substrate comprises a silicon wafer.

Y7. The structure of inventive concept Y wherein the film is formed by depositing the compound of claim 1 under hydrolyzing conditions onto the substrate.

Y8. The structure of inventive concept Y wherein the film further comprises a radical scavenging compound.

W1. A method for forming a radiation patternable coating comprising:
depositing the organometallic compound of any one of claims 1-18 onto a substrate.

W2. The method of inventive concept W1 wherein depositing comprises coating a solution of any one of inventive concepts Z-Z20.

W3. The method of inventive concept W1 wherein depositing comprises coating a solution of any one of inventive concepts Z11-Z16, and further comprising developing to form a negative tone image.

W4. The method of inventive concept W1 wherein depositing comprises coating a solution of any one of inventive concepts Z8-Z10.

W5. The method of inventive concept W4 further comprising developing to form a negative tone image.

W6. The method of inventive concept W4 further comprising developing to form a positive tone image.

W7. The method of inventive concept W1 wherein the organometallic compound has an appropriate vapor pressure and wherein depositing comprises vapor depositing the organometallic compound to form a radiation patternable coating.

In the above disclosure, it should be understood that certain terms are used interchangeably with each other. For example, one of ordinary skill in the art will understand that the terms “coating”, “layer”, and “film” are meant to construe the same idea, unless explicitly stated otherwise.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. An organometallic compound represented by the formula RSnL₃, wherein R is an organo group with 1 to 31 carbon atoms and at least two conjugated C═C bonds and forms a C—Sn bond, and each L is independently a hydrolysable ligand.

2. The organometallic compound of claim 1 wherein the C—Sn bond is radiation sensitive.

3. The organometallic compound of claim 1 wherein R comprises a conjugated diene.

4. The organometallic compound of claim 1 wherein the organo group comprises heteroatoms.

5. The organometallic compound of claim 1 wherein R comprises I, F, O or S atoms.

6. The organometallic compound of claim 1 wherein R comprises one or more fluorine atoms.

7. The organometallic compound of claim 1 wherein R comprises a —CF₃ group.

8. The organometallic compound of claim 1 wherein L is OR′, wherein R′ is an organo group with 1 to 10 carbon atoms.

9. The organometallic compound of claim 1 wherein L is NR″₂ or C≡CR″, where R″ are independently organo groups with 1-10 carbon atoms.

10. The organometallic compound of claim 1 wherein L is RSn(NMe₂)₃ or RSn(N(SiR′₃)₂)₃.

11. The organometallic compound of claim 1 wherein R comprises a methyl furan group or a methyl thiophene group.

12. The organometallic compound of claim 1 wherein R comprises a 2-ethyl-1,3-butadiene group, or a 2-methyl-1,3-butadiene group.

13. The organometallic compound of claim 1 wherein the organometallic compound is represented by Formula I: 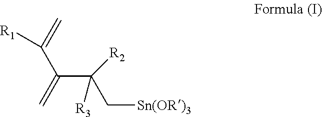
wherein R₁-R₃ are independently H, F, I, or CH₃.

14. The organometallic compound of claim 1 wherein the R comprises three conjugated C═C bonds.

15. The organometallic compound of claim 1 wherein L is OR′, wherein R′ is a methyl, ethyl, propyl, i-propyl, t-butyl, i-butyl, silyl, sec-butyl, pentan-3-yl, or t-amyl group.

16. The organometallic compound of claim 1 wherein the compound comprises 3-methylene-pent-4-en-yltin tris(tert-butyl oxide).

17. The organometallic compound of claim 1 wherein the compound comprises (furan-3-yl) methyl tin tris(tert-butyl oxide) or (thiophen-3-yl) methyl tin tris(tert-butyl oxide).

18. The organometallic compound of claim 1 wherein the R groups are capable of reacting with one another to form a bridging ligand spanning between at least two tin atoms and forming C—Sn bonds to each Sn atom.

19. A solution comprising an organic solvent and the organometallic compound of claim 1.

20. A method for forming a radiation patternable coating comprising:
depositing the solution of claim 19 onto a substrate to form a radiation sensitive organometallic film.

21. A structure comprising a radiation sensitive organometallic film and a substrate supporting the radiation patternable film on a surface, wherein the film comprises the organometallic compound of claim 1 and/or a reaction product of the organometallic compound of claim 1.

22. A method for forming a radiation patternable coating comprising:
depositing the organometallic compound of claim 1 onto a substrate.
